(19) United States
(12) Patent Application Publication
(10) Pub. No.: US 2026/0239868 A1
(43) Pub. Date: Aug. 13, 2026

(54) STRETCHABLE ELECTRODE, STRETCHABLE ORGANIC LIGHT-EMITTING DIODE COMPRISING SAME, AND METHOD FOR MANUFACTURING SAME

(71) Applicant: SEOUL NATIONAL UNIVERSITY R&DB FOUNDATION, Seoul (KR)

(72) Inventors: Tae-Woo LEE, Seoul (KR); Huanyu ZHOU, Seoul (KR); Shin Jung HAN, Chungcheongnam-do (KR)

(73) Assignee: SEOUL NATIONAL UNIVERSITY R&DB FOUNDATION, Seoul (KR)

(21) Appl. No.: 19/154,577

(22) PCT Filed: Feb. 8, 2024
(86) PCT No.: PCT/KR2024/001917

§ 371 Date: Aug. 7, 2025

(30) Foreign Application Priority Data
Feb. 10, 2023 (KR) 10-2023-0017782

(51) Int. Cl. H10K 85/10; H10K 50/17; H10K 102/00

(52) U.S. Cl. CPC H10K 85/115; H10K 85/10; H10K 85/151; H10K 50/17; H10K 2102/311

(57) ABSTRACT

The present disclosure relates to a stretchable electrode, a stretchable organic light-emitting diode comprising the same, and a method for manufacturing the stretchable electrode and the stretchable organic light-emitting diode. Specifically, the present disclosure provides a stretchable electrode having a low resistance change upon stretching and an adjustable work function, and a stretchable organic light-emitting diode that includes the same and satisfies both stretchability and high light-emitting efficiency.

### TECHNICAL FIELD

The present disclosure claims priority to and the benefit of Korean Patent Application No. 10-2023-0017782, filed in the Korean Intellectual Property Office on Feb. 10, 2023, the disclosure of which is incorporated herein by reference in its entirety.

The present disclosure relates to a stretchable electrode, a stretchable organic light-emitting diode including the same, and a method for manufacturing the stretchable electrode and the stretchable organic light-emitting diode.

### BACKGROUND ART

With the development of Internet of Things (IoT), the market size of wearable devices is significantly increasing. Among these, stretchable displays that satisfy stretchability in terms of portability and wearability of wearable devices are receiving attention, and studies on composite wearable systems using the same are being actively conducted.

Emission methods of organic light-emitting diodes (OLED) are largely divided into a phosphorescence method and a fluorescence method. An existing fluorescence method uses singlet excitons only and has internal luminous efficiency of only about 25%, and in terms of using triplet excitons as well to improve luminous efficiency, a number of studies that are being conducted are divided in the direction of a thermally activated delayed fluorescence (TADF) method using reverse inter-system crossing and the direction of a phosphorescence method using inter-system crossing.

However, no system that fully utilizes triplet excitons has been reported so far since efficient charge injection is not possible in a stretchable OLEDs, and the highest EQE reported in a stretchable organic light-emitting diode is only 3.3% as reported in the literature of Liu et. al (High-efficiency stretchable light-emitting polymers from thermally activated delayed fluorescence. Nat. Mater. 22, 737-745, 2023). Accordingly, development of a stretchable electrode capable of efficiently injecting charges in a stretchable organic light-emitting diode system remains a persistent barrier to overcome in this field.

Efficient charge injection from a stretchable electrode to the light-emitting layer is related to several important factors of the electrode such as electrical contact area, work function tunability, optical transparency, and electrical conductivity maintained even during stretching. In order to provide a stretchable electrode, attempts have been made to disperse or embed a conductive material in an elastomer having elasticity, however, due to limited electrical contact area, fixed work function and low light transmittance of conductive materials including conductive nanowires, the application to a stretchable organic light-emitting diode has been limited.

In order to resolve such problems, a conductive two-dimensional material can be introduced. After applying a two-dimensional material to a conductive nanowire surface, these are embedded together in an elastomer surface, securing properties such as work function adjustment, two-dimensional electrical contact and stretchability at the same time, and as a result, problems of an existing stretchable electrode can be resolved. This approach includes graphene, reduced graphene oxide (RGO), MXene and the like. However, graphene has a disadvantage of high cost when prepared using a chemical vapor deposition (CVD) method. In addition, although solution processability may be improved by functionalizing the surface of RGO, it is difficult to fully replace other conductive two-dimensional materials in terms of conductivity and transmittance. Accordingly, MXene is evaluated to be most preferable as a two-dimensional material capable of solution processing with high conductivity and transparency. MXene has an advantage of chemical exfoliation, however, a stability problem of MXene itself needs to be resolved in order to be used in a solution process. This problem is caused by the fact that water molecules (about 0.27 nm) may readily penetrate due to an interlayer spacing (d-spacing) of MXene flakes. Accordingly, it is necessary to resolve the unstable nature of electrode by preventing an increase in the MXene d-spacing during a solution process including aqueous solutions, and reduce the spacing to be smaller than the size of water molecules.

In addition, in order to achieve high efficiency in the field of stretchable optoelectronic devices, especially light-emitting didoes, solar cells and photodiodes, with this electrode, the need for developing a stretchable electrode is gradually increasing.

### DISCLOSURE

### Technical Problem

The first technical object to be achieved by the present disclosure is to provide a stretchable electrode capable of efficient electron and hole injection, and having high electrical conductivity and optical transmittance.

The second technical object to be achieved by the present disclosure is to provide a stretchable organic light-emitting diode having high light-emitting efficiency.

The third technical object to be achieved by the present disclosure is to provide a manufacturing method that is simple in the process and capable of manufacturing a stretchable organic light-emitting diode having high light-emitting efficiency.

However, objects to be achieved by the present disclosure are not limited to the objects mentioned above, and other objects not mentioned will be clearly appreciated by those skilled in the art from the following description.

### Technical Solution

One embodiment of the present disclosure provides a stretchable electrode comprising: a substrate formed of an elastomer; a conductive layer comprising conductive nanowires having at least some thereof being embedded in the substrate; and a two-dimensional contact layer positioned on the conductive layer and including MXene, and having an outer peripheral surface surrounded by the substrate, wherein the MXene has an interlayer spacing (d-spacing) of 1.01 nm to 1.27 nm.

Another embodiment of the present disclosure provides a stretchable organic light-emitting diode including: a cathode; an anode facing the cathode; a stretchable light-emitting layer positioned between the cathode and the anode; and a stretchable hole injection layer positioned between the anode and the stretchable light-emitting layer, wherein the cathode and the anode are the stretchable electrode.

Still another embodiment of the present disclosure provides a method for manufacturing the stretchable organic light-emitting diode, the method including: preparing the stretchable electrode; forming a stretchable hole injection layer by coating a solution for forming a stretchable hole injection layer on the stretchable electrode; forming a stretchable organic light-emitting layer by coating a solution for forming a stretchable organic light-emitting layer on the stretchable hole injection layer; and locating the stretchable electrode on the stretchable organic light-emitting layer and followed by a heat treatment process.

The preparing of the stretchable electrode may include: forming a contact layer by coating a solution including MXene on a rigid substrate as a support; adjusting an interlayer spacing (d-spacing) of the MXene to 1.01 nm to 1.27 nm by heat-treating the contact layer; forming a conductive layer by coating a solution including conductive nanowires on the heat-treated contact layer; forming a substrate by coating a solution including an elastomer on the conductive layer, and obtaining a stretchable substrate; and releasing the stretchable substrate from the support.

### Advantageous Effects

A stretchable electrode according to one embodiment of the present disclosure exhibits tunable work function characteristics and maintains minimal resistance change upon stretching.

A stretchable electrode according to one embodiment of the present disclosure has excellent moisture stability, and is suitable for a solution process.

A stretchable organic light-emitting diode according to one embodiment of the present disclosure can have high light-emitting efficiency and stretchability.

A manufacturing method according to one embodiment of the present disclosure is simple in the process, and capable of manufacturing a stretchable organic light-emitting diode having high light-emitting efficiency.

Effects of the present disclosure are not limited to the above-described effects, and effects not mentioned will be clearly appreciated by those skilled in the art from the present specification and accompanying drawings.

### BRIEF DESCRIPTION OF DRAWINGS

FIGS. 1a to 1d are cross-sectional views of a stretchable electrode according to one embodiment of the present disclosure.

FIG. 2 is a diagram schematically illustrating a charge transport path in a stretchable electrode according to one embodiment of the present disclosure.

FIG. 3 is a diagram schematically illustrating a contact layer including MXene, conductive nanowires and a MXene binder positioned at an interface when viewed from the above.

FIG. 4 is a cross-sectional view of an actuator element using a stretchable electrode according to one embodiment of the present disclosure.

FIG. 5 is a cross-sectional view of a stretchable organic light-emitting diode according to one embodiment of the present disclosure.

FIG. 6 is a cross-sectional view of a self-actuating stretchable organic light-emitting diode further including a third electrode and an electrolyte.

FIG. 7 shows a table comparing various characteristics of a self-actuating stretchable organic light-emitting diode according to one embodiment of the present disclosure and existing methods that change colors in response to external stimuli.

FIG. 8 is a diagram showing a mechanism of energy transfer from co-hosts forming an exciplex to a phosphorescent dopant.

FIG. 9 is a diagram showing examples of a material of a stretchable light-emitting layer according to one embodiment of the present disclosure.

FIG. 10 shows atomic force microscope (AFM) images for a contact layer including MXene (Mxene), a silver nanowire formed on the contact layer (Mxene/AgNW) and a MXene binder positioned at an interface between the MXene and the silver nanowire (Mxene/AgNW/binder) taken during the preparation process of Example 1.

FIG. 11 is a diagram showing Raman spectra for electrodes and SEBS prepared in Example 1 and Reference Example 1.

FIG. 12 is a diagram showing X-ray diffraction (XRD) spectra for electrodes prepared in Example 1 and Reference Example 1.

FIG. 13 is a diagram showing 0 is X-ray photoelectron spectroscopy (XPS) spectra for electrodes prepared in Example 1 and Reference Example 1.

FIG. 14 is a diagram showing Fourier transform infrared spectroscopy (FTIR) spectra for electrodes of Example 1, Reference Example 1 and Comparative Example 2.

FIG. 15 is a diagram showing experimental results on water stability for electrodes prepared in Example 1 and Comparative Example 1.

FIG. 16 shows atomic force microscopy (AFM) images of electrodes prepared in Example 1 and Comparative Example 1 with DI water after coating with DI water.

FIG. 17 is a diagram showing electrical conductivity and carrier mobility of electrodes of Example 1, Example 2 and Reference Examples 1 to 3.

FIG. 18 is a diagram showing optical transmittance at 550 nm and sheet resistance (Rs) of electrodes of Examples 1, 3 and 4.

FIG. 19 is a diagram showing work functions of electrodes of Examples 1, 3, 4 and 5.

FIG. 20a is a diagram showing results of a static stretching test on electrodes of Example 1, Example 2 and Comparative Example 2.

FIG. 20b is a diagram showing results of a cycling stretching test on electrodes of Example 1 and Comparative Example 2.

FIG. 21 shows AFM images of a MXene layer of a stretchable electrode of Example 1 taken before stretching, at the time of stretching to an elongation percentage of 40%, and after releasing.

FIG. 22a is a diagram showing Magneto-PL analysis results on TADF-based stretchable light-emitting layer (4CzIPN:PU) and phosphorescence-based stretchable light-emitting layer (Ir(ppy)₂acac:PU).

FIG. 22b is a diagram showing TRPL analysis results on TADF-based stretchable light-emitting layer (4CzIPN:PU) and phosphorescence-based stretchable light-emitting layer (Ir(ppy)₂acac:PU).

FIG. 23 shows AFM images of a stretchable light-emitting layer including thermoplastic polyurethane and an SEBS elastomer as a matrix of the light-emitting layer.

FIG. 24 shows photographs taken when stretching and twisting a phosphorescence-based stretchable light-emitting layer deposited on an SEBS elastomer substrate, and optical microscope images taken when the tensile strain (F) is 0%, 100% and 200%.

FIG. 25a is a diagram showing XPS analysis and ultraviolet photoelectron spectroscopy (UPS) analysis results depending on the depth of a stretchable hole injection layer prepared using a solution of Preparation Example 4.

FIG. 25b is a diagram showing work function and F is atomic content depending on the depth of a stretchable hole injection layer prepared using a solution of Preparation Example 4.

FIG. 26 is a diagram schematically illustrating an energy band of a stretchable organic light-emitting diode manufactured in Example 7.

FIG. 27 is a diagram showing current density, luminance, external quantum efficiency (EQE) and current efficiency of a stretchable organic light-emitting diode manufactured in Example 7.

### MODE FOR INVENTION

Throughout the specification, a description of a certain part “including” certain constituents means that it may further include other constituents, and does not exclude other constituents unless particularly stated on the contrary.

Throughout the specification, a description of a certain member being placed “on” another member includes not only a case of the certain member being in contact with the another member but a case of still another member being present between the two members.

Throughout the specification, “A and/or B” means “A and B, or A or B”.

Throughout the specification, an “actuator” means an element that allows mechanical movement by converting electrical energy into mechanical energy.

Hereinafter, the present disclosure will be described in more detail.

### <Stretchable Electrode>

In order to be used in various stretchable devices, a stretchable electrode is required to have both mechanical stretchability and high electrical conductivity. Particularly, in order to achieve a highly efficient intrinsically-stretchable organic light-emitting diode (ISOLED) that the present disclosure is to provide as a second technical object, a stretchable electrode is required to have transparency, adjustable electrode work function and achieve efficient electron and hole injection, as well as mechanical stretchability and high electrical conductivity.

One embodiment of the present disclosure provides a stretchable electrode including: a substrate including an elastomer; a conductive layer including conductive nanowires having at least some thereof being embedded in the substrate; and a contact layer positioned on the conductive layer and including MXene, and having an outer peripheral surface surrounded by the substrate, wherein the MXene has an interlayer spacing (d-spacing) of 1.01 nm to 1.27 nm.

The stretchable electrode according to one embodiment of the present disclosure includes MXene as a contact layer. Accordingly, a work function of the electrode may be readily adjusted through surface modification by substituting the MXene surface with a functional group.

The stretchable electrode according to one embodiment of the present disclosure may have a small change in resistance upon stretching, and may have high electrical conductivity and carrier mobility. Specifically, when the stretchable electrode according to one embodiment of the present disclosure has a tensile strain of 40%, the rate of change in resistance calculated by the following Equation 1 may be 100% or less. When the stretchable electrode according to one embodiment of the present disclosure has a tensile strain of 60%, the rate of change in resistance calculated by the following Equation 1 may be 300% or less.

Rate of change in resistance (%)=[(R−R₀)/R₀]×100 (R₀ is a resistance value measured for the stretchable electrode that has not undergone tensile strain, and R is a resistance value measured for the stretchable electrode that has undergone tensile strain.) [Equation 1]

In the stretchable electrode according to one embodiment of the present disclosure, the MXene has an interlayer spacing (d-spacing) of 1.01 nm to 1.27 nm, and therefore, water molecules are not able to be intercalated between the layers of the MXene. Accordingly, the stretchable electrode may have excellent moisture stability, and is suitable for a solution process.

The interlayer spacing of MXene included in the contact layer may be determined by XRD analysis. More specifically, the interlayer spacing of MXene included in the contact layer may be calculated through the 2 theta (θ) value of (002) peak in the XRD spectrum of the MXene, and the Bragg's law expressed by the following Mathematical Equation 1.

$$2 d sin θ = n λ \qquad [ Mathematical Equation 1 ]$$

(herein, d is the interlayer spacing (d-spacing), n is a constant, λ is a wavelength of X-rays, and θ is an angle between the crystal plane and the incident light.)

According to one embodiment of the present disclosure, the wavelength of X-rays may be 0.15418 nm.

The interlayer spacing of MXene included in the contact layer may be from 1.01 nm to 1.27 nm. For example, the interlayer spacing of MXene included in the contact layer may be any one of 1.01 nm, 1.02 nm, 1.03 nm, 1.04 nm, 1.05 nm, 1.06 nm, 1.07 nm, 1.08 nm, 1.09 nm, 1.10 nm, 1.11 nm, 1.12 nm, 1.13 nm, 1.14 nm, 1.15 nm, 1.16 nm, 1.17 nm, 1.18 nm, 1.19 nm, 1.20 nm, 1.21 nm, 1.22 nm, 1.23 nm, 1.24 nm, 1.25 nm, 1.26 nm and 1.27 nm. In addition, the interlayer spacing of MXene included in the contact layer may preferably be from 1.03 nm to 1.20 nm. When the interlayer spacing of MXene included in the contact layer satisfies the above-described range, solution processability of the contact layer is improved, and the stretchable electrode including the same may be used in a light-emitting diode manufactured by a solution process.

The interlayer spacing of MXene included in the contact layer may be adjusted by removing water molecules intercalated between the MXene layers while applying heat to the MXene. More specifically, the interlayer spacing of MXene included in the contact layer may be adjusted in the above-described range using methods such as heat treatment through a hot plate under a nitrogen or argon atmosphere, heat treatment through a vacuum oven and heat treatment through a hot plate in the air on the contact layer including MXene.

According to one embodiment of the present disclosure, the heat treatment temperature may be from 100° C. to 200° C. For example, the heat treatment temperature may be 100° C., 105° C., 110° C., 115° C., 120° C., 125° C., 130° C., 135° C., 140° C., 145° C., 150° C., 155° C., 160° C., 165° C., 170° C., 175° C., 180° C., 185° C., 190° C., 195° C. or 200° C. Preferably, the heat treatment temperature may be from 120° C. to 150° C.

According to one embodiment of the present disclosure, the heat treatment time may be from 5 minutes to 60 minutes. For example, the heat treatment time may be 5 minutes, 6 minutes, 7 minutes, 8 minutes, 9 minutes, 10 minutes, 11 minutes, 12 minutes, 13 minutes, 14 minutes, 15 minutes, 16 minutes, 17 minutes, 18 minutes, 19 minutes, 20 minutes, 21 minutes, 22 minutes, 23 minutes, 24 minutes, 25 minutes, 26 minutes, 27 minutes, 28 minutes, 29 minutes, 30 minutes, 31 minutes, 32 minutes, 33 minutes, 34 minutes, 35 minutes, 36 minutes, 37 minutes, 38 minutes, 39 minutes, 40 minutes, 41 minutes, 42 minutes, 43 minutes, 44 minutes, 45 minutes, 46 minutes, 47 minutes, 48 minutes, 49 minutes, 50 minutes, 51 minutes, 52 minutes, 53 minutes, 54 minutes, 55 minutes, 56 minutes, 57 minutes, 58 minutes, 59 minutes or 60 minutes.

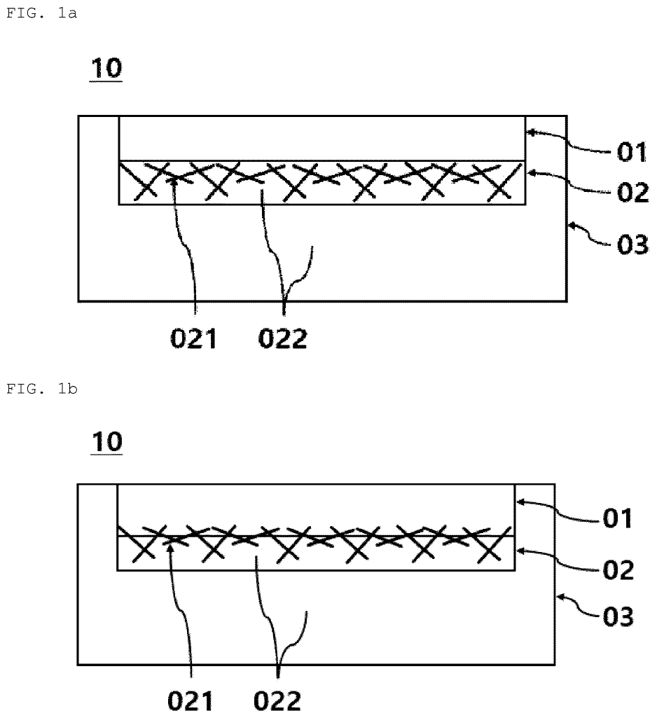

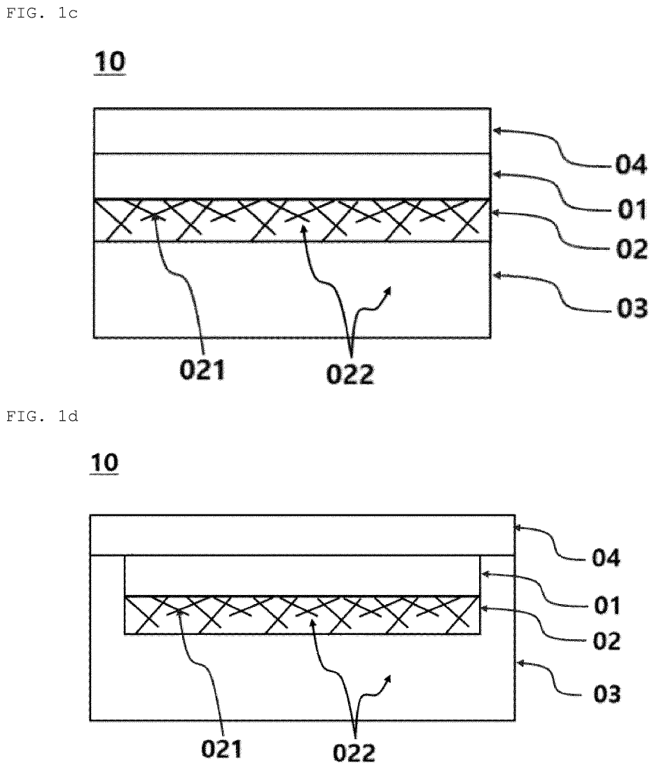

FIGS. 1a to 1d are cross-sectional views of the stretchable electrode according to one embodiment of the present disclosure.

Referring to FIGS. 1a and 1b, the stretchable electrode 10 includes a substrate 03 including an elastomer 022; a conductive layer 02 including conductive nanowires 021 having at least some thereof being embedded in the substrate 03; and a contact layer 01 positioned on the conductive layer 02 and including MXene, and an outer peripheral surface of the contact layer 01 is surrounded by the substrate 03. The stretchable electrode according to one embodiment of the present disclosure may have excellent stretchability and a small change in resistance upon stretching by having the above-described structure.

Referring to FIG. 1c, the stretchable electrode 10 may have a structure as illustrated in FIG. 1c by removing all or some of the side surface portion of the substrate 03. The size adjusting process does not affect stretchability, sheet resistance and transmittance of the electrode.

In addition, referring to FIG. 1d, the stretchable electrode 10 may further include a work function adjustment layer 04 on the contact layer 01. The work function of the electrode may be modified by further including the work function adjustment layer.

According to one embodiment of the present disclosure, the substrate may have a thickness of 1 μm to 1000 μm.

According to one embodiment of the present disclosure, the conductive nanowires having at least some thereof being embedded in the substrate may be embedded up to 1 nm to 1000 nm from the substrate surface. For example, the conductive nanowires may be embedded up to 1 nm, 2 nm, 3 nm, 4 nm, 5 nm, 6 nm, 7 nm, 8 nm, 9 nm, 10 nm, 15 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm or 1000 nm from the substrate surface.

According to one embodiment of the present disclosure, the contact layer including MXene may have a thickness of 1 nm to 100 nm. Specifically, the contact layer including MXene may have a thickness of 2 nm to 80 nm, 2 nm to 75 nm, 2 nm to 50 nm, 2 nm to 30 nm, 2 nm to 20 nm or 2 nm to 10 nm, and preferably 2 nm to 10 nm. When the contact layer including MXene has a thickness of 2 nm to 10 nm, the stretchable electrode including the same may have improved transmittance.

According to one embodiment of the present disclosure, the composition of MXene included in the contact layer may be expressed as Mₙ₊₁Xₙ or Mₙ₊₁XₙTₓ. Herein, M is a transition metal, X is carbon (C), nitrogen (N) or a combination thereof, Tₓ may mean a surface termination including oxide (O), hydroxide (OH), fluoride (F) or a combination thereof, and n may be an integer of 1 to 4. In addition, M and X are not limited to just one type, and multiple elements may be used at the same time. For example, the composition of the MXene may be expressed as Ti₂C₁Tₓ (n=1), Ti₃C₂Tₓ (n=2), Nb₄C₃Tₓ (n=3), Mo₅C₄Tₓ (n=4), V₅C₄Tₓ (n=4) or the like.

According to one embodiment of the present disclosure, the MXene may include one or more MXene flakes having a two-dimensional layered structure. One MXene flake may have a thickness of 1 nm to 5 nm, and a size of 1 μm to 100 μm.

According to one embodiment of the present disclosure, the contact layer including MXene may have a structure in which the elastomer enters a space between the MXene flakes and is half-embedded in the substrate, or may have a structure in which the elastomer is not half-embedded in the substrate.

The conductive nanowires may form a conductive network below the contact layer including MXene. Accordingly, when stretching the stretchable electrode, the distance between the MXene flakes included in the contact layer increases, resulting in cracks, however, since the conductive network formed by the conductive nanowires serves as a bridges, a conductive path may be maintained even during stretching, and as a result, there is a small change in the resistance of the electrode, and conductivity deterioration of the electrode may not occur even with continuous stretching.

According to one embodiment of the present disclosure, the conductive nanowire includes a conductive material such as conductive metal, conductive non-metal, carbon nanotube (CNT), metal oxide, metalloid or conductive polymer, and may be wire-shaped particle having an aspect ratio (length/width) of 10 or greater. For example, the conductive nanowire may be silver nanowire, copper nanowire, gold nanowire, carbon nanotube, carbon nanoplate or metal nanowire coated with a heterometal, but is not particularly limited thereto.

Preferably, the conductive nanowire may include a functional group capable of forming hydrogen bonding on the surface. By the conductive nanowire including functional groups capable of forming hydrogen bonding on the surface, the conductive nanowire may adhere to the MXene flake through hydrogen bonding with a MXene binder to be described later, and may maintain a conductive path through the conductive network without being separated from the MXene flake even with a serious level of stretching.

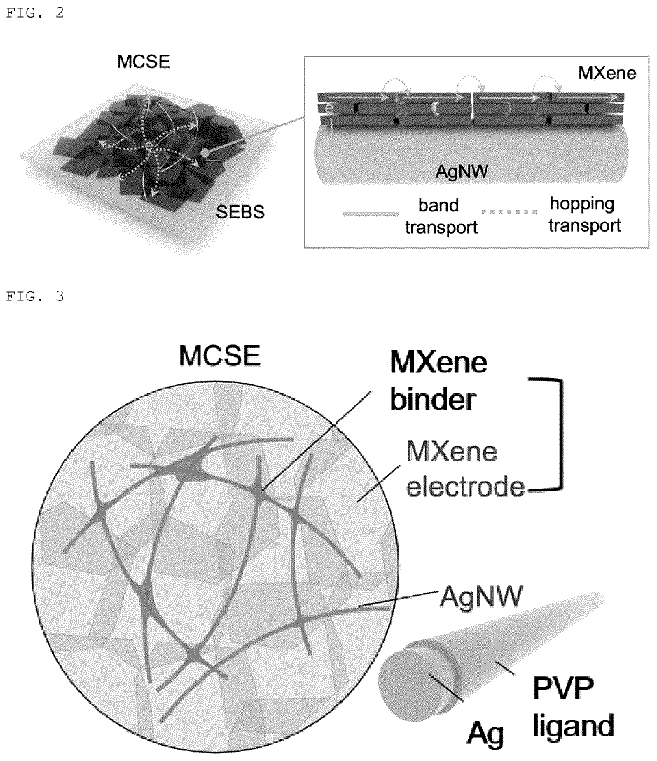

FIG. 2 is a diagram schematically illustrating a charge transport path in the stretchable electrode according to one embodiment of the present disclosure. Referring to FIG. 2, charge transport in the stretchable electrode is performed by two types of transport including hopping transport between the MXene flakes (2D material) included in the contact layer and band transport within the conductive nanowires (1D material) below the contact layer. It is known that, in the MXene flake, short-distance charge transport is dominated by band transport, whereas long-distance charge transport relies on thermally activated hopping, and this implies that hopping charge transport is a rate-determining factor in the long-distance charge transport. As the stretchable electrode includes conductive nanowires positioned below the contact layer, charge transport occurs by both hopping transport between the MXene flakes (2D material) and band transport between the conductive nanowires (1D material), and thus electrical conductivity and charge mobility may be excellent.

According to one embodiment of the present disclosure, the elastomer may be a homo copolymer including one or more types selected from the group consisting of polydimethylsiloxane (PDMS), polyurethane (PU), styrene butadiene styrene (SBS), styrene ethylene butylene styrene (SEBS), ecoflex, hydrogel, organogel, polyethylene oxide (PEO), polystyrene (PS), polycaprolactone (PCL), polyacrylonitrile (PAN), polymethyl methacrylate (PMMA), polyimide, polyvinylidene fluoride (PVDF), poly(n-vinyl carbazole) (PVK), polyvinyl chloride (PVC), derivatives thereof and combinations thereof, an alternating copolymer, a random copolymer, a block copolymer, a multiblock copolymer or a graft copolymer. According to one embodiment of the present disclosure, the elastomer described above is self-healable by including hydrogen bonds.

The stretchable electrode according to one embodiment of the present disclosure may further include a MXene binder positioned at the interface between the MXene and the conductive nanowires, as well as between adjacent conductive nanowires. This binder facilitates strong interfacial adhesion, effectively integrating the MXene flakes and conductive network.

According to one embodiment of the present disclosure, the MXene binder includes MXene expressed by Mₙ₊₁XₙTₓ, and herein, M is a transition metal, X is carbon (C), nitrogen (N) or a combination thereof, Tₓ may mean a surface termination including oxide (O), hydroxide (OH), fluorine (F) or a combination thereof, and n may be an integer of 1 to 4. By the MXene binder including a surface termination that includes oxide (O), hydroxide (OH), fluoride (F) or a combination thereof, the MXene binder may adhere MXene included in the contact layer and the conductive nanowire through hydrogen bonding.

When the stretchable electrode according to one embodiment of the present disclosure further includes the MXene binder, contact resistance may be reduced at the interface between the MXene and the conductive nanowire and the interface between the conductive nanowires, and accordingly, electrical conductivity and stretchability of the stretchable electrode may be improved.

FIG. 3 is a diagram schematically illustrating the contact layer including MXene, the conductive nanowires and the MXene binder positioned at the interface when viewed from the above. Referring to FIG. 3, the MXene binder may have intermolecular interactions such as hydrogen bonding by having surface termination groups such as fluorine groups (—F) or a hydroxide groups (—OH), and the MXene binder is present intensively at an interface where the conductive nanowires cross each other and an interface where the conductive nanowire is brought into contact with the contact layer, and serves as a binder adhering the MXene and the conductive nanowire through hydrogen bonding.

According to one embodiment of the present disclosure, the stretchable electrode may adjust a work function of the electrode by forming the work function adjustment layer through modifying the surface of the contact layer. Charge transfer occurs between a material included in the work function adjustment layer and MXene included in the contact layer, and the work function of the electrode may change while the level of electrons changes. Herein, the work function means an energy level at which electrons may exist with a probability of ½ thermodynamically.

According to one embodiment of the present disclosure, the stretchable electrode is capable of reducing the work function of the electrode through surface modification by coating a material including an electron donating group on the surface of the contact layer, and is capable of increasing the work function of the electrode through surface modification by coating a material including an electron withdrawing group on the surface of the contact layer.

According to one embodiment of the present disclosure, the stretchable electrode may have a work function of 2.0 eV to 7.0 eV. For example, the work function may include a range having a lower limit value and an upper limit value in which a smaller value of two numbers selected from among 2.0 eV, 2.1 eV, 2.2 eV, 2.3 eV, 2.4 eV, 2.5 eV, 2.6 eV, 2.7 eV, 2.8 eV, 2.9 eV, 3.0 eV, 3.1 eV, 3.2 eV, 3.3 eV, 3.4 eV, 3.5 eV, 3.6 eV, 3, 7 eV, 3.8 eV, 3.9 eV, 4.0 eV, 4.1 eV, 4.2 eV, 4.3 eV, 4.4 eV, 4.5 eV, 4.6 eV, 4.7 eV, 4.8 eV, 4.9 eV, 5.0 eV, 5.1 eV, 5.2 eV, 5.3 eV, 5.4 eV, 5.5 eV, 5.6 eV, 5.7 eV, 5.8 eV, 5.9 eV, 6.0 eV, 6.1 eV, 6.2 eV, 6.3 eV, 6.4 eV, 6.5 eV, 6.6 eV, 6.7 eV, 6.8 eV, 6.9 eV and 7.0 eV is the lower limit value and a larger value thereof is the upper limit value. More specifically, the stretchable electrode may have a work function in the range of 3.79 eV to 5.71 eV.

According to one embodiment of the present disclosure, the stretchable electrode that does not include the work function adjustment layer, that is, has a contact layer of which surface is not modified may have a work function of 4.0 eV to 5.0 eV.

According to one embodiment of the present disclosure, the work function adjustment layer may include one or more types selected from the group consisting of polyethyleneimine (PEI); polyethyleneimine ethoxylated (PEIE); Poly[(9,9-bis(3′-(N,N-dimethyl)-N-ethylammonium-propyl)-2,7-fluorene)-alt-2,7-(9,9-dioctylfluorene)] dibromide (PFN-Br); a polymer compound represented by the following Chemical Formula 1; and derivatives thereof. The stretchable electrode that includes the work function adjustment layer including the above-described material may have a smaller work function than the stretchable electrode that does not include the work function adjustment layer. Specifically, the stretchable electrode that includes the work function adjustment layer including the above-described material may have a work function of 2.0 eV to 4.0 eV. The stretchable electrode that includes the work function adjustment layer including the above-described material may be used as a cathode of a stretchable organic light-emitting diode to be described later.

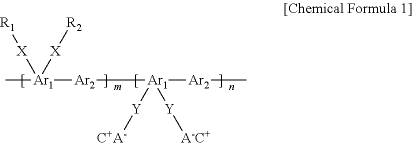

In Chemical Formula 1, Ar₁ and Ar₂ are a main chain having a conjugated structure, and each independently at least one selected from among fluorene, spirofluorene, carbazole, thiophene, phenylene, phenylene vinylene and derivatives thereof, or more specifically any one selected from the following first compound group,
m and n are each independently an integer of 1 to 1,000,000,
m:n, which is a ratio between the number of repeating units, satisfies 0.1:0.9 to 1:0,
A⁻ is any one selected from among SO₃⁻, PO₃²⁻ and CO₂⁻,
C⁺ is any one selected from among H⁺, Li⁺, Na⁺, K⁺, Rb⁺, Cs⁺ and NH₄⁺,
X is —CₙH₂ₙ—O— (n is an integer of 1 to 20), and Y is —CₙH₂ₙ— (n is an integer of 1 to 20), and
R₁ and R₂ each independently bond to carbon of a substituted or unsubstituted crown ether compound:

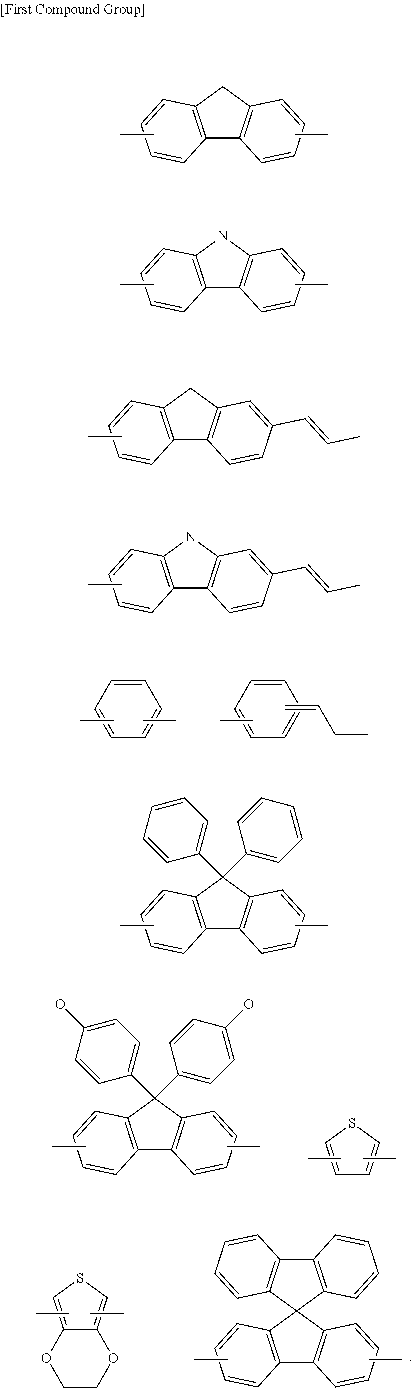

According to one embodiment of the present disclosure, the polymer compound represented by Chemical Formula 1 may be a polymer compound represented by the following Chemical Formula 2.

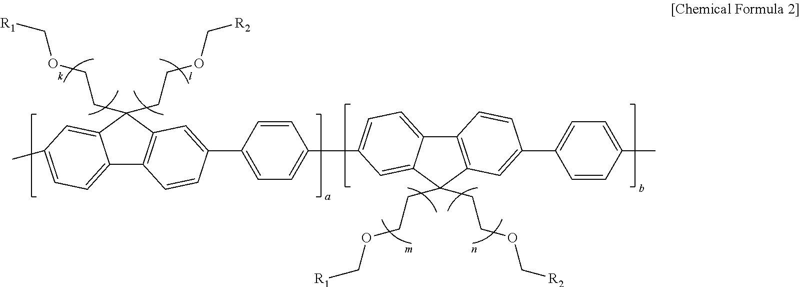

In Chemical Formula 2, k, l, m and n are each independently an integer of 1 to 10, a:b, which is a ratio between the number of repeating units, satisfies 0.1:0.9 to 1:0, X⁺ is NH₄⁺, and R₁ and R₂ each independently bond to carbon of a substituted or unsubstituted crown ether compound.

More specifically, the polymer compound represented by Chemical Formula 2 may be a polymer compound represented by the following Chemical Formula 3.

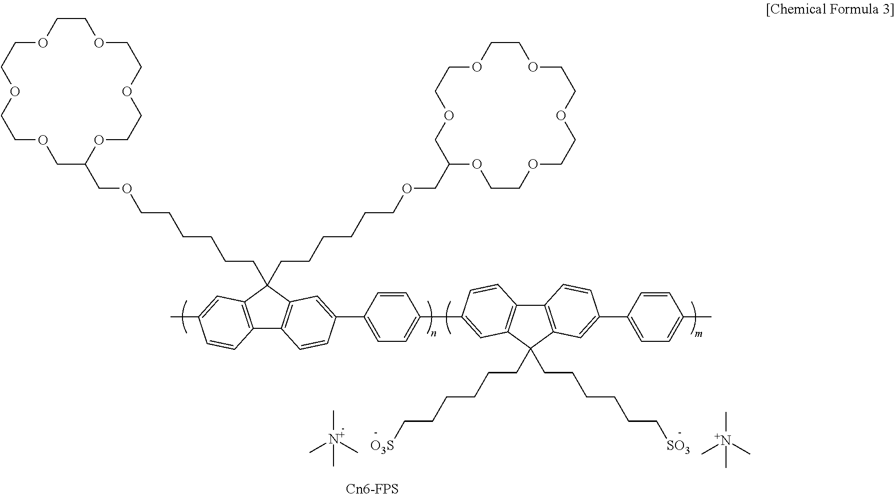

In Chemical Formula 3, n and m are each independently an integer of 1 to 100.

According to one embodiment of the present disclosure, the polymer compound represented by Chemical Formula 1 may have a weight average molecular weight of 5,000,000 g/mol or less and 500 g/mol or greater.

According to one embodiment of the present disclosure, the substituted or unsubstituted crown ether compound may be at least any one selected from the following second compound group.

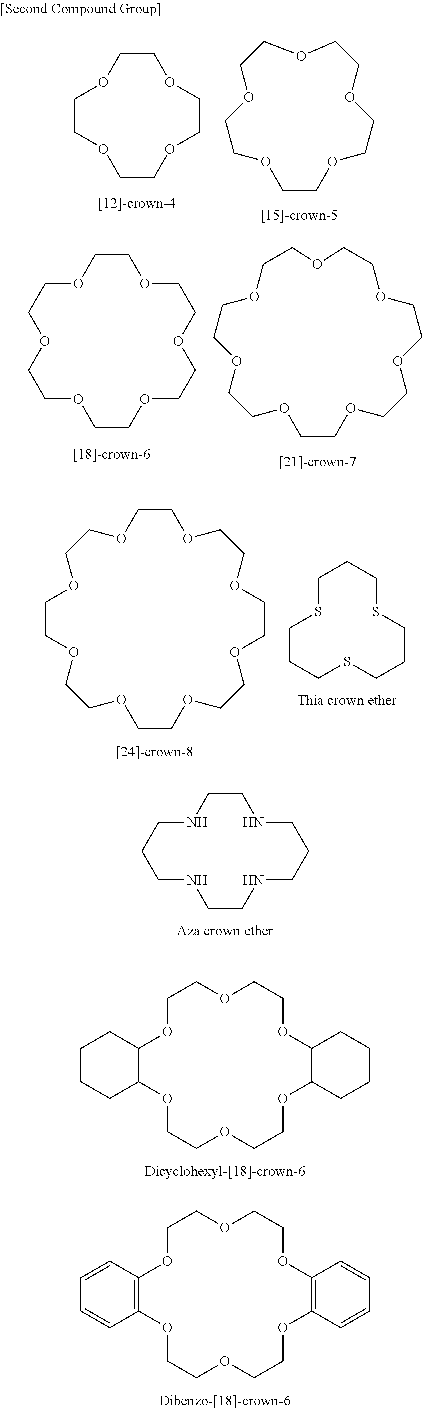

According to one embodiment of the present disclosure, the polymer compound represented by Chemical Formula 1 is a polyfluorene-based anionic conjugated polymer, and may be 18-crown-6 attached poly(fluorene-co-phenylene) sulfonate having tetramethylammonium (TMA⁺) as a counter ion.

According to one embodiment of the present disclosure, the work function adjustment layer may include one or more types selected from the group consisting of perfluorinated organic compounds, AuCl₃, HNO₃ and derivatives thereof. The stretchable electrode that includes the work function adjustment layer including the above-described material may have an increased work function compared to the stretchable electrode that does not include the work function adjustment layer. Specifically, the stretchable electrode that includes the work function adjustment layer including the above-described material may have a work function of 5.0 eV to 7.0 eV. The stretchable electrode that includes the work function adjustment layer including the above-described material may be used as an anode of a stretchable organic light-emitting diode to be described later.

According to one embodiment of the present disclosure, the perfluorinated organic compound may be a perfluorinated alkyl halide, a perfluorinated aryl halide, a fluorochloroalkene, a perfluoroalcohol, a perfluoamine, a perfluorocarboxylic acid, a perfluorosulfonic acid or a derivative thereof, but is not limited thereto. For example, the perfluorinated alkyl halide and the perfluorinated aryl halide may be trifluoroiodomethane, pentafluoroethyl iodide, perfluorooctyl bromide (perflubron), dichlorodifluoromethane and derivatives thereof. For example, the fluorochloroalkene may be chlorotrifluoroethylene, dichlorodifluoroethylene or a derivative thereof, and the perfluorocarboxylic acid may be trifluoroacetic acid, heptafluorobutyric acid, pentafluorobenzoic acid, perfluorooctanoic acid, perfluorononanoic acid or a derivative thereof. For example, the perfluorosulfonic acid may be triflic acid, perfluorobuanesulfonic acid, perfluorobutane sulfonamide, perfluorooctanesulfonic acid or a derivative thereof.

The stretchable electrode according to one embodiment of the present disclosure may have optical transmittance that satisfies 85% or greater and 95% or less, 87% or greater and 95% or less, or 90% or greater and 95% or less at a wavelength of 550 nm. By the stretchable electrode having optical transmittance that satisfies the above-described range at a wavelength of 550 nm, transparency may be satisfied, and the stretchable electrode may be suitable to be used in an organic light-emitting diode.

The stretchable electrode according to one embodiment of the present disclosure may have sheet resistance (Rs) of 40 Ω/sq or less, 35 Ω/sq or less, 30 Ω/sq or less or 5 Ω/sq or less, and 1 Ω/sq or greater.

The stretchable electrode according to one embodiment of the present disclosure may be used in a self-operatable actuator element in addition to a stretchable organic light-emitting diode to be described later. MXene is capable of ion intercalation as a two-dimensional material, and therefore, the stretchable electrode according to one embodiment of the present disclosure may be used as an electrode of an actuator element.

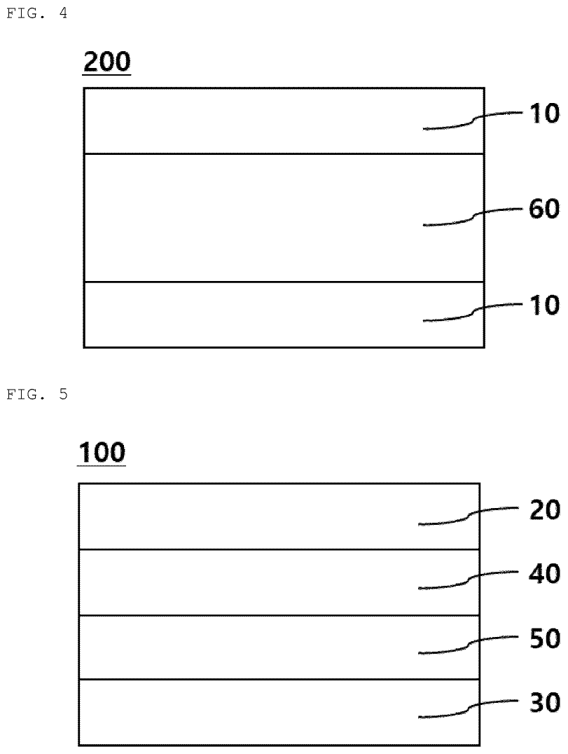

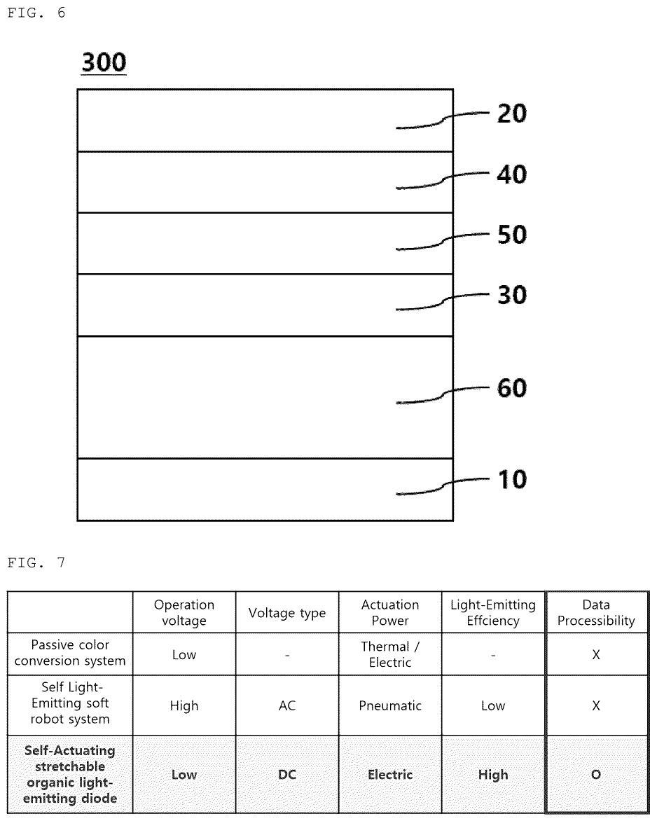

FIG. 4 is a cross-sectional view of an actuator element using the stretchable electrode according to one embodiment of the present disclosure.

According to one embodiment of the present disclosure, the actuator element 200 includes a first electrode, a second electrode facing the first electrode, and an electrolyte 60 sandwiched between the first electrode and the second electrode, wherein the first electrode and the second electrode may be the stretchable electrode 10 according to one embodiment of the present disclosure.

According to one embodiment of the present disclosure, the first electrode and the second electrode may have a polymer added thereto in order to improve adhesion with the electrolyte 60 material. For example, the first electrode and the second electrode may include a composite material in which a polymer such as PEDOT:PSS is added to a contact layer including MXene. By adding a polymer to the contact layer, properties including binding properties, electrical conductivity or ion intercalation may be improved.

According to one embodiment of the present disclosure, the electrolyte 60 may include an ionic dielectric material. The ionic dielectric material is characterized in that cations and anions form polarization or are separated by an electrical signal applied, and includes materials such as metals, ceramics, polymers, semiconductors and dielectrics including ions. However, the ionic dielectric material is not limited thereto.

For example, the ionic dielectric material may include ionic dopants selected from the group including cations of 1-ethyl-3-methylimidazolium, 1-butyl-3-methylimidazolium, methyl-tributylammonium, 1,2,3-trimethylimidazolium, methylimidazolium, 1-ethyl-2,3-dimethylimidazolium, 1-butyl-2,3-dimethylimidazolium, 1-dodecyl-3-methylimidazolium, 1-butyl-1-methylpyrrolidinium, N-methyl-N-trioctylammonium, N-butyl-N-methylpyrrolidinium, triethylsulphonium, tetraethylammonium, tetrabutylphosphonium, methyltrioctylammonium, 3-methyl-1-propylpyridinium, 1,2-dimethyl-3-propylimidazolium, 1-hexyl-3-methylimidazolium, 1-methyl-3-octylimidazolium, 1-butyl-4-methylpyridinium, 1,3-dimethylimidazolium, 4-(3-butyl-1-imidazolio)-1-butanesulfonic acid, 3-(triphenylphosphonio)propane-1-sulfonic acid, 1-allyl-3-methylimidazolium, 1-butyl-1-(3,3,4,4,5,5,6,6,7,7,8,8,8-tridecafluorooctyl)-imidazolium and 1-methyl-3-(3,3,4,4,5,5,6,6,7,7,8,8,8-tridecafluoro-octyl)-imidazolium, and anions of chloride, methanesulfonate, methylsulfate, hydrogensulfate, tetrachloroaluminate, acetate, methyl sulfate, thiocyanate, ethyl sulfate, tetrafluoroborate, dicyanamide, hexafluoroantimonate, hexafluorophosphate, bis(trifluoromethyl sulfonyl)imide, trifluoromethane sulfonate, iodide, nitrate, bromide, bis(pentafluoroethylsulfonyl)-imide, tosylate, octyl sulfate, bis(2,4,4-trimethyl-pentyl)phosphinate, decanoate, thiosalicylate, triflate2-(2-methoxyethoxy)-ethyl sulfate, nonafluorobutanesulfonate, benzoate and heptadecafluorooctanesulfonate, or may include blends thereof.

### <Stretchable Organic Light-Emitting Diode>

Another embodiment of the present disclosure provides a stretchable organic light-emitting diode including: a cathode; an anode facing the cathode; a stretchable light-emitting layer positioned between the cathode and the anode; and a stretchable hole injection layer positioned between the anode and the stretchable light-emitting layer, wherein the cathode and the anode are the stretchable electrode.

The stretchable organic light-emitting diode according to one embodiment of the present disclosure has high light-emitting efficiency and may have stretchability.

FIG. 5 is a cross-sectional view of the stretchable organic light-emitting diode according to one embodiment of the present disclosure.

The stretchable organic light-emitting diode 100 according to one embodiment of the present disclosure includes a cathode 20, an anode 30 facing the cathode 20, a stretchable light-emitting layer 40 positioned between the cathode 20 and the anode 30, and a stretchable hole injection layer 50 positioned between the anode 30 and the stretchable light-emitting layer 40, wherein the cathode and the anode are the stretchable electrode according to one embodiment of the present disclosure described above. As necessary, the stretchable organic light-emitting diode 100 may further include at least one of an electron injection layer (not shown) and an electron transport layer (not shown) between the cathode 20 and the stretchable light-emitting layer 40, and may further include a hole transport layer (not shown) between the stretchable light-emitting layer 40 and the stretchable hole injection layer 50.

The stretchable organic light-emitting diode according to one embodiment of the present disclosure may further include a third electrode and an electrolyte, and by further including a third electrode and an electrolyte, a self-actuating stretchable organic light-emitting diode capable of outputting an electrical signal in the forms of light and movement at the same time may be provided.

FIG. 6 is a cross-sectional view of the self-actuating stretchable organic light-emitting diode further including a third electrode and an electrolyte.

According to one embodiment of the present disclosure, the self-actuating stretchable organic light-emitting diode 300 may include a stretchable electrode 10 as the third electrode facing the anode 30, and an electrolyte 60 interposed between the stretchable electrode 10 and the anode 30 in the stretchable organic light-emitting diode according to the present disclosure. The stretchable electrode as the third electrode may be the stretchable electrode according to one embodiment of the present disclosure.

According to one embodiment of the present disclosure, the self-actuating stretchable organic light-emitting diode may emit light by receiving an electrical signal, and may generate its own mechanical movement at the same time. In other words, the self-actuating stretchable organic light-emitting diode may implement either light or movement, or both light and movement as an actuator and display. In addition, the self-actuating stretchable organic light-emitting diode may have low driving voltage, direct current driving, and high electric light-emitting efficiency.

Furthermore, the self-actuating stretchable organic light-emitting diode amplifies an external micro-stimulation signal and outputs the signal as movement and light, mimicking functions of displaying a signal of danger and avoiding danger, and accordingly, may be used in soft robots, neural prosthetics and prosthetic forms.

FIG. 7 shows a table comparing various characteristics of the self-actuating stretchable organic light-emitting diode according to one embodiment of the present disclosure and existing methods that change colors in response to external stimuli.

Examples of existing methods to obtain a multimodal-type display device capable of outputting signals not only through a light form but also through mechanical movement of the display device may include passive color changing systems (passive method) as disclosed in literatures (ACS Nano 2017, 11, 11350/Adv. Func. Mater. 2019, 29, 1806383/Adv. Func. Mater. 2018, 28, 1801847/Proc. Natl. Acad. Sci. U.S.A 2014, 111, 12998), and self-luminous soft robot systems (active method) as disclosed in literatures (Science 2016, 351, 107/Nat. Mater. 2020, 19, 182). Referring to FIG. 7, the self-actuating stretchable organic light-emitting diode according to one embodiment of the present disclosure may have low driving voltage, direct current driving, and favorable electric light-emitting efficiency compared to multimodal-type display devices in existing manners.

Hereinafter, the stretchable light-emitting layer and the stretchable hole injection layer included in the stretchable organic light-emitting diode according to one embodiment of the present disclosure will be described in more detail.

### <Stretchable Light-Emitting Layer>

The stretchable light-emitting layer 40 performs a role of generating luminescence by combining holes (h) introduced from the anode and electrons (e) introduced from the cathode to form excitons, and emitting light as the excitons move to the ground state.

According to one embodiment of the present disclosure, the stretchable light-emitting layer may include a thermoplastic polyurethane matrix; a co-host dispersed in the thermoplastic polyurethane matrix and forming an exciplex; and a phosphorescent dopant dispersed in the thermoplastic polyurethane matrix.

By the stretchable organic light-emitting diode according to one embodiment of the present disclosure including the stretchable light-emitting layer, the stretchable organic light-emitting diode may maintain a high level of light-emitting efficiency even during stretching, and may withstand tensile strain of 200% by being mechanically strong.

In order to efficiently collect triplets in the stretchable light-emitting layer, non-radioactive triplets need to be converted into radioactive singlets or triplets through a spin-flip process. In a stretchable organic light-emitting diode using an existing TADF-type light-emitting layer, an intermolecular distance included in the light-emitting layer may change when mechanical strain caused by stretching is applied, and spin-orbit coupling (SOC) may be reduced accordingly. The decrease in SOC caused by stretching inhibits the spin-flip process, resulting in a decrease in the triplet collection efficiency. On the other hand, the stretchable light-emitting layer includes a phosphorescent dopant having strong SOC dispersed in the thermoplastic polyurethane matrix, and accordingly, the triplet collection efficiency may be maintained high even under mechanical strain caused by stretching.

FIG. 8 is a diagram showing a mechanism of energy transfer from the co-host forming an exciplex to the phosphorescent dopant. Referring to FIG. 8, the co-host formed with an electron transporting host (TPBi) and a hole transporting host (TCTA) may form an exciplex, and energy of the exciplex is transferred to the phosphorescent dopant (Ir(ppy)₂acac) via Forster resonance energy transfer. Herein, since this energy transfer is not affected by external stretching, a stretchable light-emitting layer capable of maintaining a high level of light-emitting efficiency may be provided even during stretching. In addition, the stretchable light-emitting layer has an expanded recombination region by including the co-host forming an exciplex, thereby achieving balanced charge carrier injection.

According to one embodiment of the present disclosure, the co-host forming an exciplex may be formed by a combination of an electron transporting host and a hole transporting host.

The electron transporting host may include known electron transport materials. For example, the electron transporting host may include at least one selected from the group consisting of quinoline derivatives, particularly, tris(8-hydroxyquinoline) aluminum (Alq3), bis(2-methyl-8-quinolinolate)-4-(phenylphenolato)aluminum (Balq), bis(10-hydroxybenzo[h]quinolinato)-beryllium (Bebq2), 2,9-dimethyl-4,7-diphenyl-1,10-phenanthroline (BCP), 4,7-diphenyl-1,10-phenanthroline (Bphen), 2,2′,2″-(benzene-1,3,5-triyl)-tris(1-phenyl-1H-benzimidazole) (TPBI), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), tris(2,4,6-trimethyl-3-(pyridin-3-yl)phenyl)borane (3TPYMB), phenyl-dipyrenylphosphine oxide (POPy2), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl)phenyl]benzene (BmPyPhB), bis(10-hydroxybenzo[h]quinolinato)beryllium (Bepq2), diphenylbis(4-(pyridin-3-yl)phenyl)silane (DPPS), 1,3,5-tri(p-pyrid-3-yl-phenyl)benzene (TpPyPB), 1,3-bis[2-(2,2′-bipyridin-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), TSPO1 (diphenylphosphine oxide-4-(triphenylsilyl)phenyl), TPBi (1,3,5-tris(N-phenylbenzimidazol-2-yl)benzene), tris(8-quinolinolate)aluminum (Alq3), 2,5-diaryl silol derivatives (PyPySPyPy), perfluorinated compounds (PF-6P) and COTs (octasubstituted cyclooctatetraene), but is not limited thereto.

The hole transporting host may include known hole transport materials. For example, the hole transporting host may include at least one selected from the group consisting of 1,3-bis(carbazol-9-yl)benzene (MCP), 1,3,5-tris(carbazol-9-yl)benzene (TCP), 4,4′,4″-tris(carbazol-9-yl)triphenylamine (TCTA), 4,4′-bis(carbazol-9-yl)biphenyl (CBP), N,N′-bis(naphthalen-1-yl)-N,N′-bis(phenyl)-benzidine (NPB), N,N′-bis(naphthalen-2-yl)-N,N′-bis(phenyl)-benzidine (R-NPB), N,N′-bis(naphthalen-1-yl)-N,N′-bis(phenyl)-2,2′-dimethylbenzidine (α-NPD), di-[4-(N,N-ditolyl-amino)-phenyl]cyclohexane (TAPC), N,N,N′,N′-tetra-naphthalen-2-yl-benzidine (β-TNB), N4,N4,N4′,N4′-tetra(biphenyl-4-yl)biphenyl-4,4′-diamine (TPD15), poly(9,9-dioctylfluorene-co-bis-N,N′-(4-butylphenyl)-bis-N,N′-phenyl-1,4-phenylenediamine) (PFB), poly(9,9′-dioctylfluorene-co-N-(4-butylphenyl)diphenylamine) (TFB), poly(9,9′-dioctylfluorene-co-bis-N,N′-(4-butylphenyl)-bis-N, N′-phenylbenzidine) (BFB), poly(9,9-dioctylfluorene-co-bis-N,N′-(4-methoxyphenyl)-bis-N,N′-phenyl-1 and 4-phenylenediamine (PFMO), but is not limited thereto.

The combination of the hole transporting host and the electron transporting host forming an exciplex may be, for example, mCP:B3PYMPM, TCTA:B3PYMPM, TCTA:TPBi, TCTA:3TPYMB, TCTA:BmPyPB, TCTA:BSFM, CBP:B3PYMPM or NPB:BSFM, and may preferably be a combination of TCTA:TPBi. When the hole transporting host and the electron transporting host are a combination of TCTA:TPBi, the face-to-face alignment of the planar structures of TPBi and TCTA may minimize the change in spin-orbit coupling (SOC) of the exciplex depending on the change in the thermoplastic polyurethane matrix concentration.

According to one embodiment of the present disclosure, by the stretchable light-emitting layer including the thermoplastic polyurethane matrix, photoluminescence (PL) intensity and lifetime of the light-emitting layer may be improved due to trap dilution, and a high level of light-emitting efficiency may be maintained even during stretching since the co-host and the phosphorescent dopant dispersed in the matrix are favorably dispersed and do not cause phase separation.

According to one embodiment of the present disclosure, the phosphorescent dopant may have smaller triplet energy than the exciplex. Specifically, the phosphorescent dopant may be a complex of a heavy metal such as iridium (Ir), platinum (Pt), osmium (Os), ruthenium (II) or rhenium (Re) and an organic ligand.

For example, the phosphorescent dopant may be one or more types selected from the group consisting of (Ir(ppy)₂acac), Ir(ppy)₃, Ir(ppy)₂(bpmp), Ir(3mppy)₃, Ir(dmppy-pro)₂tmd, Ir(npy)₂acac, Ir(mppy)₃, fac-Ir(ppy)₃, FIr4mpic, Ir(Fppy)₃, Ir(tfpd)₂pic, FK306, FCNIrPic, fac-Ir(dpbic)₃, mer-Ir(pmi)₃, FIrN4, Bepp2, mer-Ir(pmb)₃, fac-Ir(Pmb)₃, FIr6 (bis(2,4-difluorophenylpyridinato)-tetrakis(1-pyrazolyl)borate iridium(III)), Ir(piq-dm)₂(acac), Ir(dmpq)₂(acac), Eu(TTA)₃phen, Ir(2-phq)₂(acac), Ir(2-phq)₃, Ir(piq)₂(acac), Ir(piq)₃, Ir(phq)₂tpy, Hex-Ir(phq)₂(acac), Ir(flq)₂(acac), Ir(dmppy-ph)₂tmd, Ir(ppy)₃-Bp and Ir(dmpq)₃, but is not particularly limited thereto. The names of the materials are expressed as product names or abbreviations.

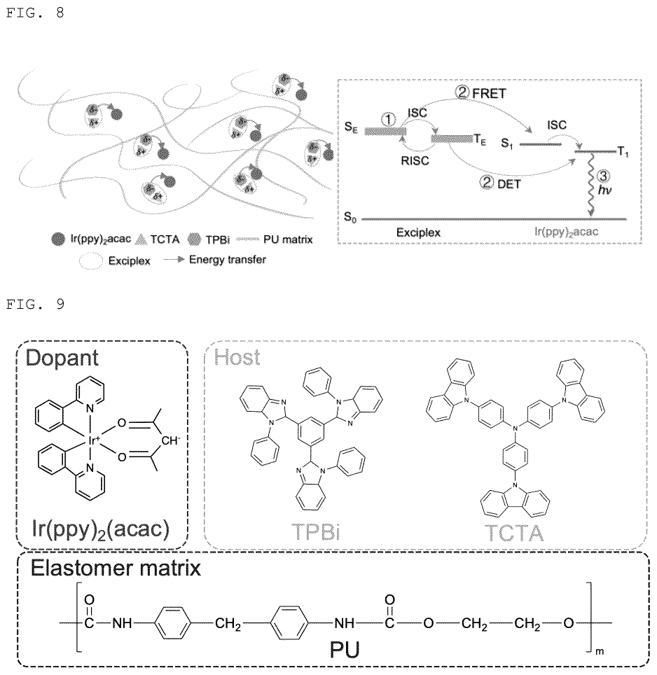

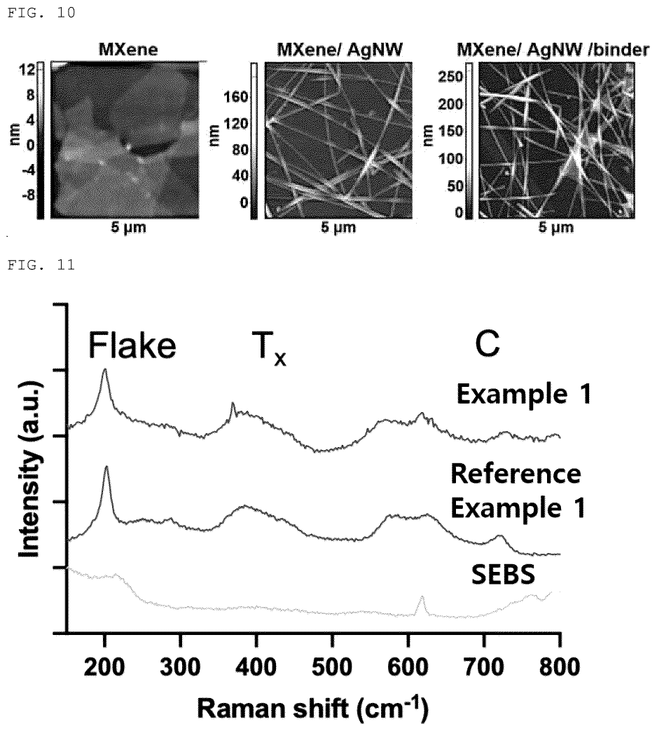

FIG. 9 is a diagram showing examples of the material of the stretchable light-emitting layer according to one embodiment of the present disclosure.

### <Stretchable Hole Injection Layer>

According to one embodiment of the present disclosure, the stretchable hole injection layer may include a surfactant, a conductive polymer and a perfluorinated ionomer. By the stretchable hole injection layer including a surfactant, a conductive polymer and a perfluorinated ionomer, the stretchable hole injection layer may have a work function gradually increasing in the thickness direction from the electrode to the surface of the stretchable hole injection layer, and may achieve excellent stretchability. Specifically, a self-assembled layer in which fluorine atoms are concentrated near the surface of the stretchable hole injection layer is formed due to the low surface energy of the perfluorinated ionomer, reducing the fluorine content in a thickness direction of the stretchable hole injection layer, and accordingly, the work function may gradually change. The surfactant may reduce a glass transition temperature of the materials of the stretchable hole injection layer as a plasticizer, thereby securing stretchability.

According to one embodiment of the present disclosure, the conductive polymer may include materials commonly used in the art, and those described as an example of the conductive polymer included in the conductive material layer of the stretchable electrode may also be used. Preferably, the conductive polymer may include PEDOT:PSS (poly(3,4-ethylenedioxythiophene) polystyrene sulfonate). When the conductive polymer includes PEDOT:PSS, phase separation between the PEDOT and the PSS is induced by the surfactant, and stretchability of the stretchable hole injection layer may be further improved.

According to one embodiment of the present disclosure, the perfluorinated compound may be a perfluorinated alkyl halide, a perfluorinated aryl halide, a fluorochloroalkene, a perfluoroalcohol, a perfluoamine, a perfluorocarboxylic acid, a perfluorosulfonic acid or a derivative thereof, but is not limited thereto. For example, the perfluorinated alkyl halide and the perfluorinated aryl halide may be trifluoroiodomethane, pentafluoroethyl iodide, perfluorooctyl bromide (perflubron), dichlorodifluoromethane and derivatives thereof. For example, the fluorochloroalkene may be chlorotrifluoroethylene, dichlorodifluoroethylene or a derivative thereof, and the perfluorocarboxylic acid may be trifluoroacetic acid, heptafluorobutyric acid, pentafluorobenzoic acid, perfluorooctanoic acid, perfluorononanoic acid or a derivative thereof. For example, the perfluorosulfonic acid may be triflic acid, perfluorobuanesulfonic acid, perfluorobutane sulfonamide, perfluorooctanesulfonic acid or a derivative thereof.

According to one embodiment of the present disclosure, the surfactant is an amphipathic material simultaneously having two opposing functional groups of hydrophilic group and hydrophobic group in the same molecule, and may perform a role of showing various physical phenomena by being adsorbed at a boundary surface between a liquid and a gas, a liquid and a liquid, or a liquid and a solid. The surfactant may perform a role of lowering surface tension, emulsifying, improving wettability and foamability, or solubilizing. Particularly, when the surfactant performs a ligand role by bonding to the surface of a nanoparticle through a coordinate bond, dispersibility of the nanoparticle may increase. Examples of the surfactant may include anionic surfactants (forms including sulfate (for example: ammonium lauryl sulfate, sodium lauryl sulfate, sodium dodecyl sulfate, sodium laureth sulfate, sodium myreth sulfate), sulfonate (for example: dioctyl sodium sulfosuccinate, perfluorooctanesulfonate, perfluorobutanesulfonate, linear alkylbenzne sulfates), phosphate esters, and carboxylates (for example: sodium stearate, sodium lauryl sarcosinate, perfluorononanoate, perfluorooctanoate)), cationic surfactants (forms including primary, secondary, tertiary and quaternary ammonium cations), quaternary ammonium cations such as benzalkonium chloride, dimethyldioctadecylammonium chloride, trimethyl glycine and choline, zwitterionic (amphoteric) surfactants having both cations and anions in the same material, and nonionic surfactants such as long chain alcohols including fatty alcohols, cetyl alcohol, stearyl alcohol, cetostearyl alcohol (consisting predominantly of cetyl and stearyl alcohols), oleyl alcohol and the like.

According to one embodiment of the present disclosure, the nonionic surfactant may include one selected from the group consisting of polysorbate, polyethylene glycol (PEG), nonoxynol-9, octoxynol-9 (Triton X-100), alkyl polyglucoside (APG), ethylene oxide/propylene oxide copolymers, derivatives thereof and combinations thereof. For example, product names of the compound that may be used as the nonionic surfactant may include Zonyl FS-300, Zonyl FSN, Zonyl FSN-100, Zonyl FSO-100, ACH SN104, Andisi1 SP 19, ECO Tween 20, ECO Tween 40, ECO Tween 60, ECO Tween 80, ECO Tween 85, Span, Triton X-100, Triton X-102, Triton X-114, Triton X-405 and Triton X-4.

### <Method for Manufacturing Stretchable Organic Light-Emitting Diode>

Another embodiment of the present disclosure provides a method for manufacturing the stretchable organic light-emitting diode, the method including: preparing the stretchable electrode; forming a stretchable hole injection layer by coating a solution for forming a stretchable hole injection layer on the stretchable electrode; forming a stretchable organic light-emitting layer by coating a solution for forming a stretchable organic light-emitting layer on the stretchable hole injection layer; and laminating the stretchable electrode onto the stretchable organic light-emitting layer and heat-treating the result.

The preparing of the stretchable electrode may include: forming a contact layer by coating a solution including MXene on a substrate; adjusting an interlayer spacing (d-spacing) of the MXene to 1.01 nm to 1.27 nm by heat-treating the contact layer; forming a conductive layer by coating a solution including conductive nanowires on the heat-treated contact layer; forming a substrate by coating a solution including an elastomer on the conductive layer, and obtaining a electrode; and releasing the electrode from the substrate.

As the preparing of the stretchable electrode includes the adjusting of an interlayer spacing (d-spacing) of the MXene to 1.01 nm to 1.27 nm by annealing the contact layer, the prepared electrode has moisture stability, and is suitable to be used in a solution process since deterioration and damage do not occur on the electrode in a moisture-containing environment.

According to one embodiment of the present disclosure, the temperature of heat-treating the contact layer may be from 100° C. to 200° C. For example, the temperature may be 100° C., 105° C., 110° C., 115° C., 120° C., 125° C., 130° C., 135° C., 140° C., 145° C., 150° C., 155° C., 160° C., 165° C., 170° C., 175° C., 180° C., 185° C., 190° C., 195° C. or 200° C. Preferably, the temperature may be from 120° C. to 150° C.

The manufacturing method according to the present disclosure is a solution process, and each solution used herein may include the components described above for the stretchable organic light-emitting diode and the stretchable electrode according to the present disclosure, and an appropriate solvent for each of the components.

According to one embodiment of the present disclosure, the concentration of the MXene solution used in the forming of a contact layer may be from 4 mg/mL to 15 mg/mL. Specifically, the concentration of the MXene solution may have a range having a lower limit value and an upper limit value in which a smaller value of two numbers selected from among 4 mg/mL, 5 mg/mL, 6 mg/mL, 7 mg/mL, 8, mg/mL, 9 mg/mL, 10 mg/mL, 11 mg/mL, 12 mg/mL, 13 mg/mL, 14 mg/mL and 15 mg/mL is the lower limit value and a larger value thereof is the upper limit value. By the concentration of the MXene solution satisfying the above-described range, a contact layer having a film form may be formed, and the contact layer may have excellent conductivity.

According to one embodiment of the present disclosure, the preparing of the stretchable electrode may further include, before the forming of the contact layer, conductive layer and, forming a MXene binder by coating a diluted MXene solution on the conductive layer, and deposition of insulating elastomer.

According to one embodiment of the present disclosure, the concentration of the diluted MXene solution may be 0.1 mg/mL or greater and 3 mg/mL or less. Specifically, the concentration of the diluted MXene solution may have a range having a lower limit value and an upper limit value in which a smaller value of two numbers selected from among 0.1 mg/mL, 0.2 mg/mL, 0.3 mg/mL, 0.4 mg/mL, 0.5 mg/mL, 0.6 mg/mL, 0.7 mg/mL, 0.8 mg/mL, 0.9 mg/mL, 1.0 mg/mL, 1.1 mg/mL, 1.2 mg/mL, 1.3 mg/mL, 1.4 mg/mL, 1.5 mg/mL, 1.6 mg/mL, 1.7 mg/mL, 1.8 mg/mL, 1.9 mg/mL, 2.0 mg/mL, 2.1 mg/mL, 2.2 mg/mL, 2.3 mg/mL, 2.4 mg/mL, 2.5 mg/mL, 2.6 mg/mL, 2.7 mg/mL, 2.8 mg/mL, 2.9 mg/mL and 3.0 mg/mL is the lower limit value and a larger value thereof is the upper limit value. By the concentration of the diluted MXene solution satisfying the above-described range, a film layer separate from the contact layer is not formed in the process of forming a MXene binder, and the diluted MXene solution moves to an interface between the conductive nanowire and the MXene by a capillary phenomenon, facilitating interactions such as hydrogen bonding at the interface, and thereby securing adhesive strength.

The method of coating the solution is not particularly limited in the manufacturing method of the present disclosure, and for example, methods of spin-coating, drop casting or ink-jet printing may be used.

According to one embodiment of the present disclosure, the forming of a contact layer in the preparing of the stretchable electrode may be preferably performed by spin coating. When the forming of a contact layer is performed by spin coating, water molecules that may be intercalated between the MXene layers are removed, and the interlayer spacing of the MXene may be favorably adjusted in the heat-treating of the contact layer.

### <Bio-Neuromimetic System>

Another embodiment of the present disclosure may provide a bio-neuromimetic system using the stretchable organic light-emitting diode according to the present disclosure.

Specifically, the stretchable organic light-emitting diode according to the present disclosure may be used as an output device of a bio-neuromimetic system.

The bio-neuromimetic system may include a sensory nervous system device, a motor nervous system device and an artificial synaptic device. The artificial synaptic device receives a pre-synaptic signal and outputs the pre-synaptic signal as a post-synaptic signal, and performs a role of processing a sensory signal coming from at least one artificial sensor or body organ to control and stimulate at least one artificial motor organ or body organ.

In addition, the bio-neuromimetic system using the self-actuating stretchable organic light-emitting diode according to the present disclosure capable of outputting an electrical signal in the forms of light and movement at the same time may mimic functions of displaying a signal of danger and avoiding danger by amplifying an external micro-stimulation signal and outputting the signal as movement and light, and accordingly, may be used in soft robots, neural prosthetics and prosthetic forms.

As for the details regarding the bio-neuromimetic system, contents described in the Korean Patent Application Laid-Open No. 10-2023-0162561, and the Korean Patent Nos. 10-2191817 and 10-2246807 may be included in the present disclosure.

Hereinafter, the present disclosure will be described in detail with reference to examples in order to specifically describe the present disclosure. However, examples according to the present disclosure may be modified to various different forms, and the scope of the present disclosure is not construed as being limited to the examples described below. Examples of the present specification are provided in order to more fully describe the present disclosure to those having average knowledge in the art.

### Preparation Example 1: Synthesis of MXene

MXene (Ti₃C₂Tₓ) was synthesized using a method described in the prior literature (Huanyu Zhou et al., Adv. Mater. 2022, 34, 2206377).

### Preparation Example 2: Preparation of Cn6-FPS

Cn6-FPS (18-crown-6 attached poly(fluorene-co-phenylene) sulfonate with tetramethylammonium (TMA+) counterions) represented by the following chemical formula was synthesized using a method described in the prior literature (Huanyu Zhou et al., Adv. Mater. 2022, 34, 2203040).

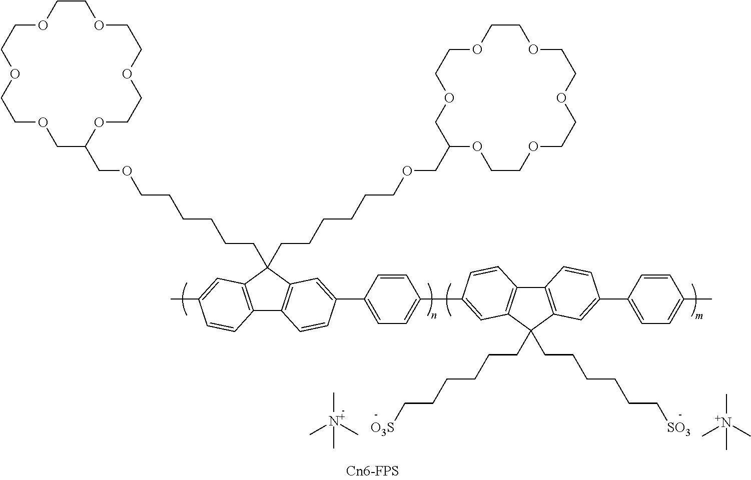

### <Stretchable Electrode>

### Example 1: Preparation of MXene-Contact Stretchable Electrode (MCSE)

First, a glass substrate was ultrasonic treated using acetone and isopropyl alcohol (IPA) as a solvent, and the glass substrate was subjected to ultraviolet cleaning (UV Ozone) treatment for 15 minutes. Then, a solution including the MXene prepared in Preparation Example 1 (8 mg/mL in DI water) was coated so as to cover the surface of the glass substrate, which was left for 3 minutes for self-assembly. Then, the result was spin-coated at 2000 rpm for 60 seconds, and spin-coated at 6000 rpm for 90 seconds to evaporate the solvent of the MXene solution, and a contact layer including MXene was formed on the glass substrate.

The glass substrate coated with the contact layer was heat-treated for 2 hours at a temperature of 150° C. in a glove box under a nitrogen atmosphere to reduce the interlayer spacing of MXene included in the contact layer.

Then, a solution including silver nanowires (AgNW) (2.5 mg/mL in isopropyl alcohol (IPA)) was coated on the contact layer, and spin-coated at 2000 rpm for 60 seconds to form a conductive layer including AgNW. Then, the result was heat-treated for 10 minutes at a temperature of 120° C. under an air atmosphere to facilitate interactions at both interfaces between AgNW/AgNW and between AgNW/MXene.

In order to further improve interactions at the interfaces, a diluted MXene solution including the MXene of Preparation Example 1 (0.5 mg/mL in DI water) was coated on the conductive layer, and spin-coated at 2000 rpm for 60 seconds to form a MXene binder, which is positioned at the interfaces between AgNW/AgNW and between AgNW/MXene and adheres AgNW/AgNW and AgNW/MXene through hydrogen bonding.

Then, 0.4 mL of a solution including an SEBS (styrene-ethylene/butylene-styrene copolymer, Asahi Kasei™ H1062) elastomer (180 mg/mL in toluene) was coated on the conductive layer using a drop cast method, and the solvent was evaporated to form a substrate. Herein, the SEBS solution was coated so as to fully cover the formed conductive layer and contact layer in order to obtain a structure in which the outer peripheral surface of the contact layer is surrounded by the substrate in the final electrode.

Then, the stack of glass substrate-MXene contact layer-AgNW conductive layer-SEBS was placed in water to separate the glass substrate from the laminate, and as a result, a MXene-contact stretchable electrode was prepared.

### Example 2

A MXene-contact stretchable electrode was prepared in the same manner as in Example 1, except that the MXene binder was not formed.

### Example 3: Preparation of MXene-Contact Stretchable Electrode for Anode Application (A-MCSE) with Increased Work Function

In order to prepare A-MCSE having a high work function for anode application, a diluted solution of perfluorosulfonic acid (PFSA) (2 wt % in IPA) was spin-coated on the contact layer of the MCSE prepared in Example 1 at 3000 rpm for 60 seconds, and then heat-treated for 5 minutes at 100° C. to form a work function adjustment layer.

### Example 4: Preparation of MXene-Contact Stretchable Electrode for Cathode Application (C-MCSE) with Decreased Work Function

In order to prepare C-MCSE having a low work function for cathode application, a solution of polyethyleneimine (PEI, Sigma-Aldrich) (0.5 wt % in 2-methoxyethanol) was spin-coated on the contact layer of the MCSE prepared in Example 1 at 3000 rpm for 60 seconds, and then heat-treated for 5 minutes at 90° C. to form a work function adjustment layer.

### Example 5: Preparation of MXene-Contact Stretchable Electrode for Cathode Application (C-MCSE) with Decreased Work Function

In order to prepare C-MCSE having a low work function for cathode application, the solution including Cn6-FPS of Preparation Example 2 (1.5 mg/mL in 2-methoxyethanol) was spin-coated on the contact layer of the MCSE prepared in Example 1 at 3000 rpm for 60 seconds, and then heat-treated for 5 minutes at 90° C. to form a work function adjustment layer.

### Example 6: Pattern-Formed MXene-Contact Stretchable Electrode

A pattern-formed MXene-contact stretchable electrode was prepared in the same manner as in Example 1, except that, a photoresist pattern layer was formed on the glass substrate as follows before forming the contact layer including MXene in Example 1, and the pattern layer was removed by immersing the glass substrate in acetone for 30 seconds before separating the electrode laminate from the glass substrate.

First, a positive photoresist (PR, AZ GXR-601) was coated on the glass substrate, and coated at 4000 rpm for 60 seconds to form a photoresist layer having a thickness of 1 pam, and subsequently, the photoresist layer was soft-baked for 3 minutes at 120° C. to remove the solvent and improve adhesive strength with the glass substrate. Then, the substrate was irradiated with UV to form a bank structure for a follow-up patterning process, and the substrate was immersed in a developing solution (AZ 300 MIF) for 30 seconds. The substrate was thoroughly rinsed with deionized water (DIW) to remove an excessive developing solution, and hard-baked for 3 minutes at 120° C. to ensure complete cross-linking of the photoresist, and as a result, the photoresist pattern layer was formed on the glass substrate.

### Reference Example 1

First, a glass substrate was ultrasonic treated using acetone and isopropyl alcohol (IPA) as a solvent, and the glass substrate was subjected to ultraviolet cleaning (UV Ozone) treatment for 15 minutes.

Then, a MXene solution (8 mg/mL in DI water) was coated so as to cover the surface of the glass substrate, which was left for 3 minutes. The result was first spin-coated at 2000 rpm for 60 seconds, and second spin-coated at 6000 rpm for 90 seconds to evaporate the solvent of the MXene solution, and a MXene layer was formed on the glass substrate. The MXene layer-formed glass substrate was heat-treated for 2 hours at a temperature of 150° C. in a glove box under a nitrogen atmosphere to reduce the interlayer spacing of the MXene, and as a result, an electrode formed with the MXene layer-glass substrate was obtained.

### Reference Example 2

The MXene layer-coated glass substrate obtained in Reference Example 1 was heat-treated for 2 hours at a temperature of 150° C. in a glove box under a nitrogen atmosphere. Then, a solution including silver nanowires (AgNW) (2.5 mg/mL in isopropyl alcohol (IPA)) was coated on the MXene layer, and spin-coated at 2000 rpm for 60 seconds to locate silver nanowires on the MXene layer, and then the result was heat-treated for 10 minutes at a temperature of 120° C. under an air atmosphere to obtain an electrode formed with the conductive layer including silver nanowires-MXene layer-glass substrate.

### Reference Example 3

For the laminate of conductive layer-MXene layer-glass substrate obtained in Reference Example 2, a diluted MXene solution (0.5 mg/mL in DI water) including the MXene of Preparation Example 1 was coated on the conductive layer, and spin-coated at 2000 rpm for 60 seconds to form a MXene binder, and as a result, an electrode formed with the MXene binder-formed conductive layer-MXene layer-glass substrate was obtained.

### Comparative Example 1

A stretchable electrode was prepared in the same manner as in Example 1, except that the contact layer-coated glass substrate was not heat-treated, and the interlayer spacing of MXene was not reduced.

### Comparative Example 2

First, a glass substrate was ultrasonic treated using acetone and isopropyl alcohol (IPA) as a solvent. Then, a solution including silver nanowires (AgNW) (2.5 mg/mL in isopropyl alcohol (IPA)) was coated on the glass substrate, spin-coated twice each at 2000 rpm for 60 seconds, and heat-treated for 10 minutes at a temperature of 150° C. under an air atmosphere to facilitate interactions at an AgNW/AgNW interface.

Then, 0.4 mL of a solution including an SEBS (styrene-ethylene/butylene-styrene copolymer, Asahi Kasei™ H1062) elastomer (180 mg/mL in toluene) was coated on the silver nanowires using a drop cast method, and the solvent was evaporated to form a substrate. The result was placed in water to separate the glass substrate, and as a result, a stretchable electrode in which silver nanowires are embedded in the SEBS substrate was prepared.

### Comparative Example 3

First, single-layer graphene was grown on copper (Cu) foil using a chemical vapor deposition (CVD) method. Specifically, copper foil was inserted into a quartz tube, heated to 1060° C. using 15 sccm of H₂, and then annealed for 30 minutes. Then, CH₄ gas, a graphene precursor, was supplied for 30 minutes at 60 sccm to grow graphene, and then the result was rapidly cooled to room temperature to synthesize a single-layer graphene film on copper foil.

A poly (methyl methacrylate) (PMMA) (996k, Sigma-Aldrich) solution (4.6 g/100 ml chlorobenzene solvent) was spin-coated on the graphene/copper foil as a supporting polymer, and then dried for 1 hour in the air. Then, the copper foil was removed for 5 hours using an ammonium persulfate ((NH₄)₂S₂O₈) etchant, and the PMMA/graphene film was floated on deionized water to wash away the residual etchant. The graphene on the copper foil surface was rolled into a scroll shape due to surface tension, and subsequently, the PMMA/graphene film decorated with graphene scroll was transferred to a washed glass substrate, and rinsed with acetone for 1 hour to remove the PMMA supporting layer, and as a result, an electrode formed with the graphene layer-glass substrate was obtained.

### Experimental Example 1. Analysis on Properties of MXene-Contact Stretchable Electrode

### (1) Observation of MXene Layer and Conductive Nanowire Shape

In order to observe shapes of the contact layer including MXene, the silver nanowire formed on the contact layer and the MXene binder positioned at an interface between the MXene and the silver nanowire, which were formed during the preparation process of Example 1, each image was taken using an atomic force microscope (NX-10, Park System).

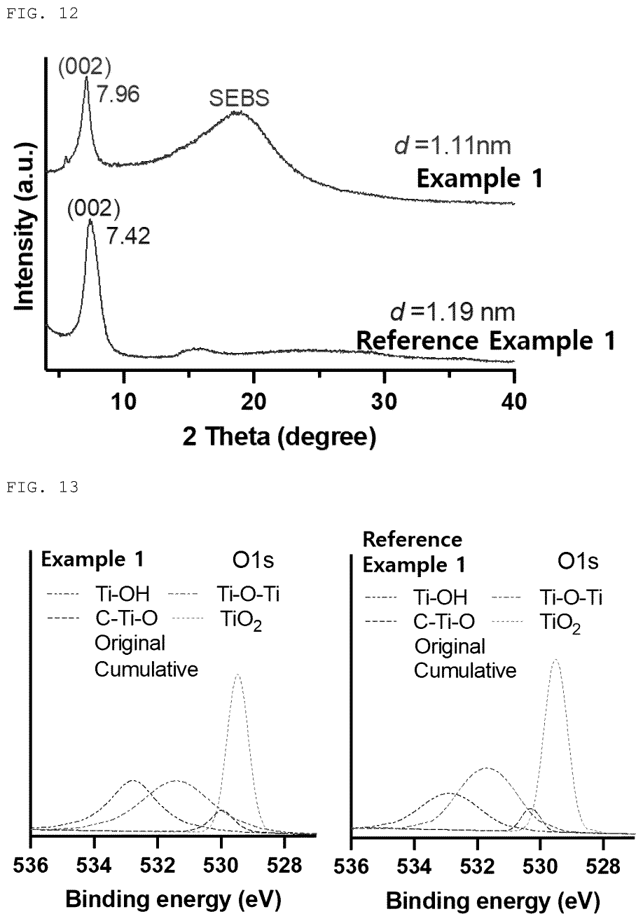

FIG. 10 shows atomic force microscope (AFM) images for the contact layer including MXene (Mxene), the silver nanowire formed on the contact layer (Mxene/AgNW) and the MXene binder positioned at an interface between the MXene and the silver nanowire (Mxene/AgNW/binder) taken during the preparation process of Example 1.

Referring to FIG. 10, it was identified that the MXene binder was positioned at an interface where the silver nanowires cross each other and an interface where the silver nanowire is brought into contact with the MXene layer.

### (2) Analysis on Physicochemical Properties of MXene-Contact Stretchable Electrode

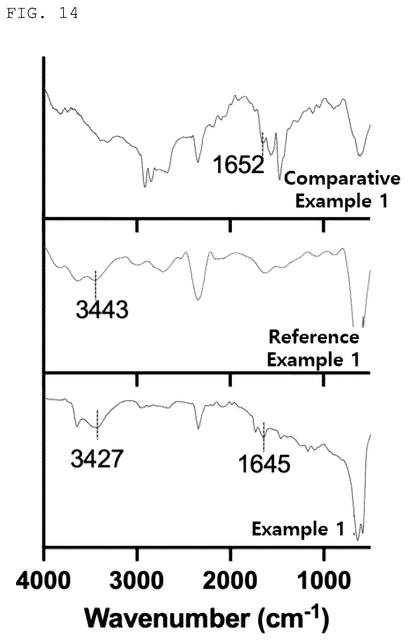

Raman spectroscopy analysis was performed on the electrodes and SEBS prepared in Example 1 and Reference Example 1. FIG. 11 is a diagram showing Raman spectra for the electrodes and SEBS prepared in Example 1 and Reference Example 1. Referring to FIG. 11, a peak corresponding to MXene (flake), a peak corresponding to the surface termination group of MXene (Tx) and a peak corresponding to SEBS were observed in the electrode prepared in Example 1, and it was identified that the contact layer including MXene was transferred well without being separated from the SEBS during the preparation process of Example 1.

An X-ray diffraction (XRD) analysis was performed on the electrodes prepared in Example 1, Reference Example 1 and Comparative Example 1 to measure the interlayer spacing of MXene. FIG. 12 is a diagram showing XRD graphs for the electrodes prepared in Example 1 and Reference Example 1. Referring to FIG. 12, the interlayer spacing of MXene was measured to be 1.11 nm and 1.19 nm, which is less than 1.27 nm that is the size of water molecules, in the electrodes of the Example 1 and Reference Example 1 in which the heat treatment was performed on the MXene layer (the contact layer including MXene), and therefore, it was identified that the electrodes were suitable for a solution process. However, the interlayer spacing of MXene measured for the electrode of Comparative Example 1 in which no heat treatment was performed on the contact layer including MXene was 1.33 nm, which is larger than 1.27 nm, and therefore, deterioration caused by intercalation of water molecules was expected when using the electrode in a solution process.

In order to identify the degree of hydrogen bonding, a high resolution O is XPS analysis was performed on the electrodes prepared in Example 1 and Reference Example 1, and a Fourier transform infrared spectroscopy (FT-IR) analysis was performed on the electrodes of Example 1, Reference Example 1 and Comparative Example 2. FIG. 13 is a diagram showing 0 is XPS spectra for the electrodes prepared in Example 1 and Reference Example 1. FIG. 14 is a diagram showing FT-IR spectra for the electrodes of Example 1, Reference Example 1 and Comparative Example 2. Referring to FIG. 13, it may be identified that the intensity of the peak corresponding to Ti—OH, which represents a hydrogen bond, is stronger in the electrode of Example 1 than in the electrode of Reference Example 1. In addition, referring to FIG. 14, it was identified that the peak of 1652 cm⁻¹ corresponding to the silver nanowire identifiable in the FR-IR spectrum of Comparative Example 1 shifted to 1645⁻¹ in the FR-IR spectrum of Example 1, and the peak of 3443 cm⁻¹ corresponding to the MXene identifiable in the FR-IR spectrum of Reference Example 1 shifted to 3427⁻¹ in the FR-IR spectrum of Example 1. Such shifts in the peaks imply that hydrogen bonding increases at interfaces between the MXene and the silver nanowire and between the silver nanowires due to the presence of the MXene binder.

### (3) Identification of Moisture Stability Depending on Adjustment of Interlayer Spacing of MXene

For the electrode of Example 1 in which the interlayer spacing of MXene was measured to be 1.11 nm and the electrode of Comparative Example 1 in which the interlayer spacing of MXene was measured to be 1.33 nm, hydration stability of the electrodes was evaluated.

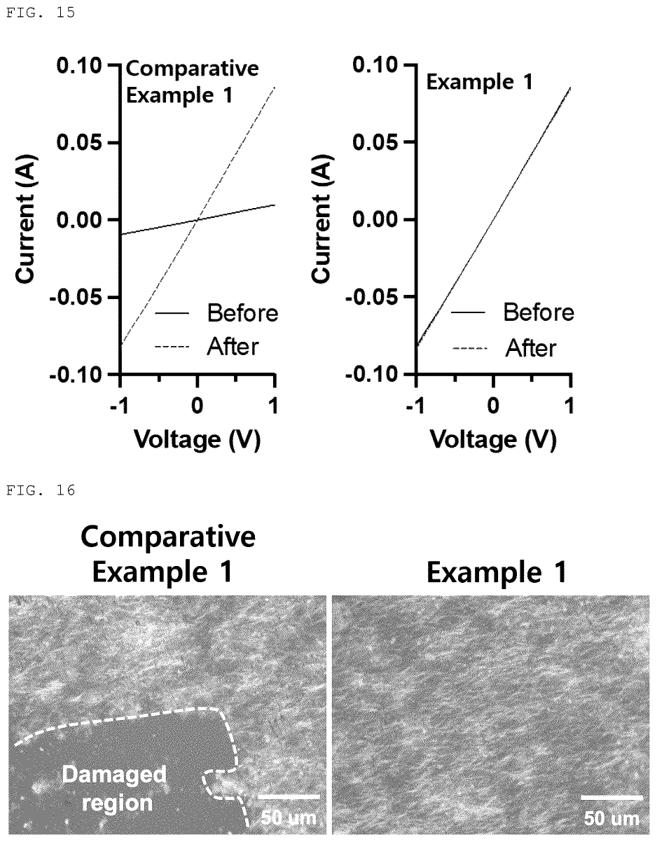

Specifically, for the hydration stability experiment, electrical contacts of the electrodes were shielded using a copper tape so that contact resistance was not affected. Before and after coating the electrodes with DI water, changes in the slope of the current-voltage curve were measured by scanning the electrodes from −2 V to 2 V in 0.1 V increments using a Keithley 2400 source meter. FIG. 15 is a diagram showing the experimental results on hydration stability for the electrodes prepared in Example 1 and Comparative Example 1. FIG. 16 shows AFM images of the contact layer including MXene taken after coating the electrodes prepared in Example 1 and Comparative Example 1 with DI water. Referring to FIGS. 15 and 16, it was identified that the electrode of Comparative Example 1 in which no heat treatment was performed on the contact layer including MXene showed significant performance degradation and had a damaged region appearing after coated with DI water, whereas the electrode of Example 1 in which heat treatment was performed on the contact layer including MXene had excellent stability for moisture with no performance degradation and no morphological changes after coated with DI water.

### (4) Analysis on Optical and Electrical Properties of MXene-Contact Stretchable Electrode

For the electrodes of Example 1, Example 2 and Reference Examples 1 to 3, electrical conductivity and carrier mobility were measured.

In order to secure experimental stability from the influence of moisture, electrical contacts of the electrodes were shielded using a copper tape to prevent the influence of the spin-coated film on the contact resistance. Electrical conductivity of the electrodes was calculated by measuring changes in the slope of the current-voltage curve through scanning the electrodes from −2 V to 2 V in 0.1 V increments using a Keithley 2400 source meter, and carrier mobility was measured using a Hall-effect analysis (HMS-5000, Ecopia Co. Ltd).

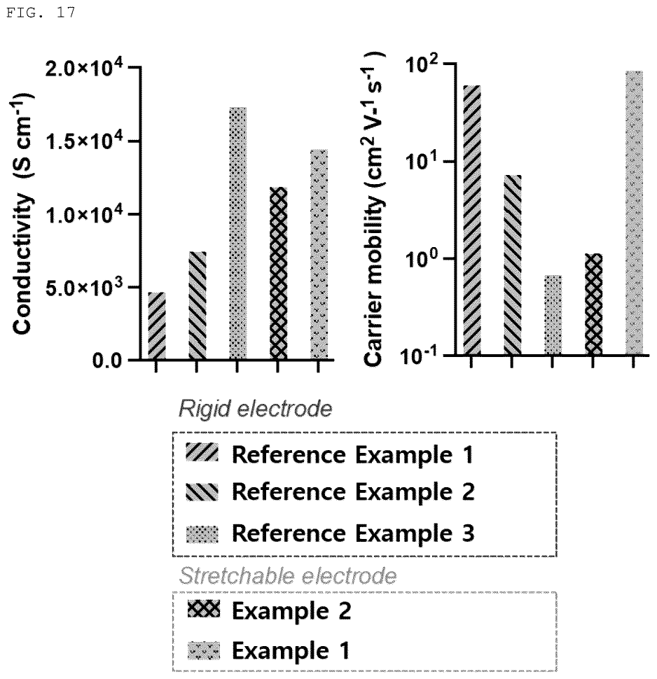

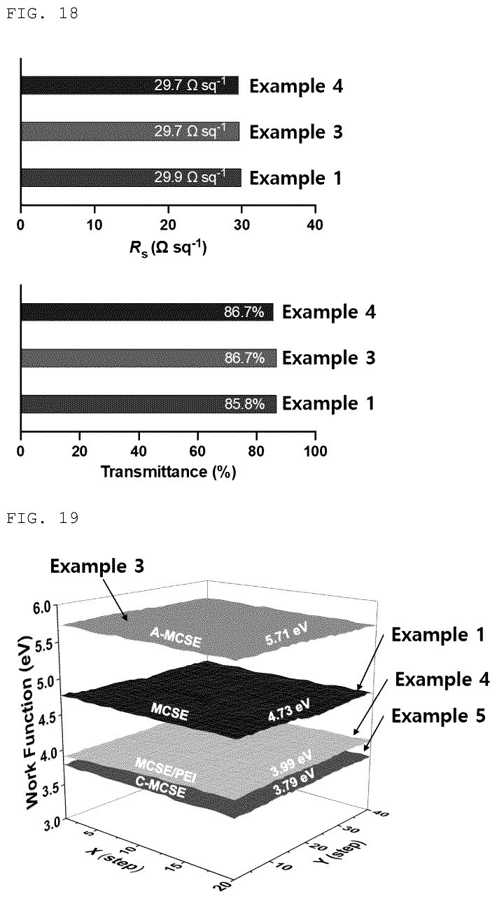

FIG. 17 is a diagram showing electrical conductivity and carrier mobility of the electrodes of Example 1, Example 2 and Reference Examples 1 to 3.

Referring to FIG. 17, the contact surface is the surface of the MXene layer where the silver nanowires are located in the electrodes of Reference Examples 1 to 3, and therefore, electrical conductivity was improved, whereas carrier mobility was reduced when coating the silver nanowires on the MXene layer and further forming the MXene binder. On the other hand, in the electrodes of Examples 1 and 2, the silver nanowires are present between the MXene layer and the SEBS substrate and not exposed to the contact surface, and therefore, both electrical conductivity and carrier mobility were excellent. Furthermore, it was identified that carrier mobility significantly increased in the electrode of Example 1 in which the MXene binder was further formed.

For the electrodes of Examples 1, 3 and 4, optical transmittance at 550 nm and sheet resistance were measured. Optical transmittance was measured by UV-visible spectroscopy using a spectrophotometer (PerkinElmer, Lambda 465), and sheet resistance (Rs) was determined using a method of four-point probe connected to a Keithley 2400 source meter.

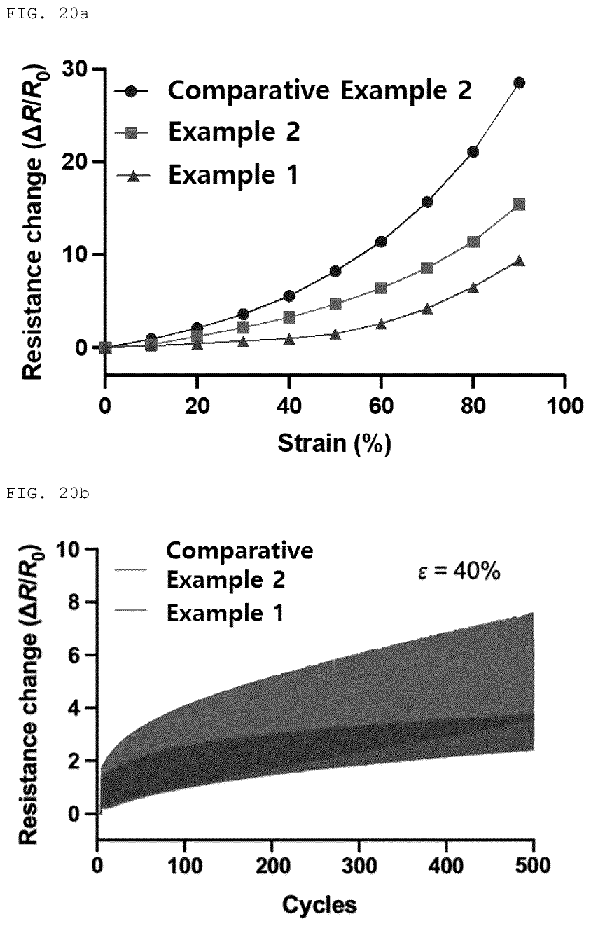

FIG. 18 is a diagram showing optical transmittance at 550 nm and sheet resistance (Rs) of the electrodes of Examples 1, 3 and 4. Referring to FIG. 18, it was identified that all the electrodes of Example 1, 3 and 4 had excellent transparency with optical transmittance satisfying 85% or greater at 550 nm, and had excellent conductivity with sheet resistance satisfying 30 Ω/sq or less.

Furthermore, for the electrodes of Reference Example 1 and Comparative Example 3, sheet resistance of the MXene layer and the graphene layer was measured in the same manner as above. The MXene layer of Reference Example 1 had sheet resistance of 120 Ω/sq and the graphene layer of Comparative Example 3 had sheet resistance of 500 Ω/sq, and it was identified that the MXene layer had significantly lower sheet resistance compared to the graphene layer.

### (5) Work Function of MXene-Contact Stretchable Electrode

Work Functions of the electrodes of Examples 1, 3, 4 and 5 were measured using ultraviolet photoelectron spectroscopy (UPS).

The work function was measured using an ultraviolet photoelectron spectroscopy measuring device (AXIS Ultra DLD, Kratos Inc.) equipped with a helium-gas discharge lamp (exciton energy of 21.2 eV and energy resolution of 200 meV) and having a sampling area of 100 μm in diameter, and static electricity accumulation was reduced using a 15 V sample bias.

FIG. 19 is a diagram showing work functions of the electrodes of Examples 1, 3, 4 and 5. Referring to FIG. 19, the MXene-contact stretchable electrode of which surface was not modified (MCSE) had a work function of 4.73 eV, the MXene-contact stretchable electrode of which surface was modified with PFSA (A-MCSE) had a work function of 5.71 eV, the MXene-contact stretchable electrode of which surface was modified with PEI (MCSE/PEI) had a work function of 3.99 eV, and the MXene-contact stretchable electrode of which surface was modified with Crown-CPE (C-MCSE) had a work function of 3.79 eV. It was identified that the work function was able to be adjusted to be in a range of 3.70 eV to 5.71 eV depending on the surface modification material.

### (6) Stretching Test on MXene-Contact Stretchable Electrode

For each of the electrodes of Example 1, Example 2 and Comparative Example 2, a static stretching test and a cycling stretching test were performed.

In the static stretching test, the electrode was attached to a custom-made stretching device, and in order to maintain consistent contact resistance, the contact was fixed on a rigid part of the stretching device. Eutectic gallium-indium (EGaIn) was applied to the contact area, and the area was supplemented with a copper tape as a contact pad. Linear resistance between the copper contact pads was recorded using a Keithley 6500 digital multi-meter. The stretching device stretched the electrode specimen having an initial length of 10 mm at a rate of 10 mm/minute until the tensile strain of the specimen reached 100%. In the cycling stretching test, a cycle of stretching the electrode specimen from the tensile strain of 0% to the tensile strain of 40% at 100 mm min⁻¹ through real-time measurement of resistance was performed 500 times.

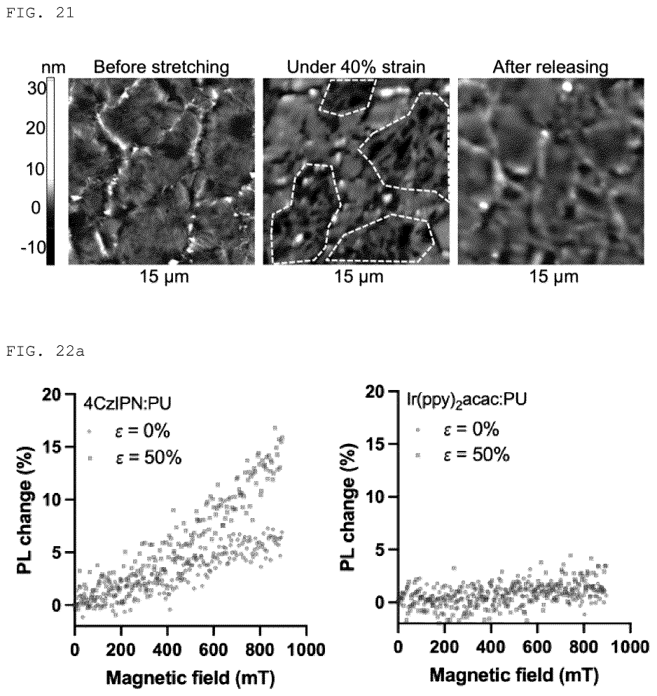

FIG. 20a is a diagram showing the results of the static stretching test on the electrodes of Example 1, Example 2 and Comparative Example 2. FIG. 20b is a diagram showing the results of the cycling stretching test on the electrodes of Example 1 and Comparative Example 2.

In the following Table 1, a rate of change in the resistance calculated by the following Equation 1 depending on the tensile strain is shown for the electrodes of Example 1, Example 2 and Comparative Example 2.

Rate of change in resistance (%)=[(R−R₀)/R₀]×100 (R₀ is a resistance value measured for the stretchable electrode that has not undergone tensile strain, and R is a resistance value measured for the stretchable electrode that has undergone tensile strain.) [Equation 1]

TABLE 1

| | Tensile | | | | | |
|---|---|---|---|---|---|---|
| | Strain | 20% | 40% | 60% | 80% | 90% |
| Rate of | Comparative | 209% | 553% | 1140% | 2108% | 2849% |
| Change in | Example 2 | | | | | |
| Resistance = | Example 2 | 122% | 327% | 640% | 1140% | 1540% |
| [ (R-Ro) / | Example 1 | 42% | 98% | 256% | 654% | 940% |
| Ro] × 100 | | | | | | |

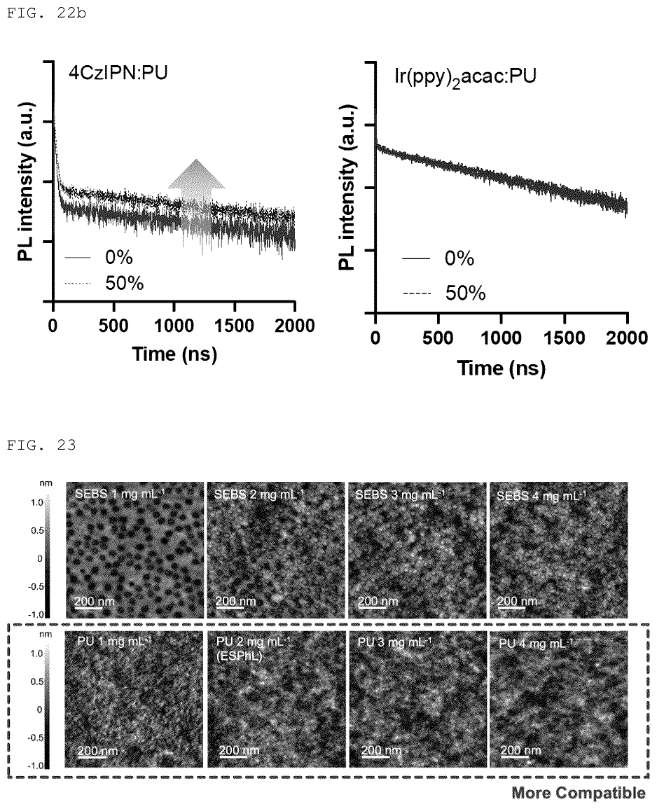

Referring to FIG. 20a and Table 1, it was identified that the electrode according to one embodiment of the present disclosure had a smaller change in the resistance when the tensile strain increases compared to Comparative Example 2, which is an existing electrode in which silver nanowires are impregnated in an elastomer base. In addition, it was identified that the electrode of Example 1 in which a MXene binder was formed had a significantly reduced change in the resistance upon strain caused by stretching. In addition, referring to FIG. 20b, the process of stretching the electrode to a tensile strain of 40% and releasing was repeated in the cycling stretching test, and it was identified that the electrode according to the present disclosure had a small change in the resistance depending on the number of cycle repetitions. FIG. 21 shows AFM images of the MXene layer of the stretchable electrode of Example 1 taken before stretching, at the time of stretching to an elongation percentage of 40%, and after releasing. Referring to FIG. 21, open cracks occur when stretching the electrode specimen to a tensile strain of 40%, however, the silver nanowires act as a bridge across the cracks, maintaining electrical conductivity. In other words, this implies that, since MXene is a two-dimensional material, the conductive network formed by silver nanowires may provide a path for electricity to flow (conducting path) even when cracks occur with stretching.

### <Stretchable Light-Emitting Layer>

### Preparation Example 3: Solution for Forming Phosphorescence-Based Stretchable Light-Emitting Layer

Thermoplastic polyurethane (PU, Tecoflex SG-80A) was dissolved in a solvent having a volume-to-volume ratio between cyclohexanone and tetrahydrofuran (THF) of 10:1 to obtain a thermoplastic polyurethane solution (2 mg/mL).

The thermoplastic polyurethane solution was stirred for 1 hour or longer in a glove box, and then (Ir(ppy)₂acac) (0.9 mg) as a phosphorescent dopant, and TCTA (5 mg) and TPBi (5 mg) as a co-host were dissolved in the thermoplastic polyurethane solution (1 mL) in the same glove box to prepare a solution for forming a phosphorescence-based stretchable light-emitting layer.

### Comparative Preparation Example 1: Solution for Forming TADF-Based Stretchable Light-Emitting Layer

4CzIPN was dissolved in the thermoplastic polyurethane solution obtained in Preparation Example 3 at a concentration of 1.5 mg/mL to prepare a solution for forming a TADF-based stretchable light-emitting layer.

### Comparative Preparation Example 2: Solution for Forming Stretchable Light-Emitting Layer Using SEES Elastomer

A solution for forming a phosphorescence-based stretchable light-emitting layer was prepared in the same manner as in Preparation Example 3, except that a solution including an SEBS (styrene-ethylene/butylene-styrene copolymer, Asahi Kasei™ H1062) elastomer (180 mg/mL in toluene) was used instead of the thermoplastic polyurethane solution.

### Experimental Example 2. Analysis on Properties of Stretchable Light-Emitting Layer

### (1) Comparative Experiment on TADF-Based Light-Emitting Layer and Phosphorescence-Based Stretchable Light-Emitting Layer

First, each of the solutions for forming a stretchable light-emitting layer prepared in Preparation Example 3 and Comparative Preparation Example 1 was spin-coated on an SEBS substrate at 2000 rpm for 60 seconds, and then a TADF-based stretchable light-emitting layer prepared from Preparation Example 3 and a phosphorescence-based stretchable light-emitting layer prepared from Comparative Preparation Example 1 were prepared as test specimens.

For the stretchable light-emitting layers prepared from Preparation Example 3 and Comparative Preparation Example 1, magneto photoluminescence (Magneto-PL) and time resolved photoluminescence (TRPL) analyses were performed. Magneto-PL and time resolved photoluminescence analyses were each performed on the stretchable light-emitting layers in a normal state and in a state stretched to a strain (F) of 50%.

Magneto-PL recorded PL intensity as a function of magnetic field using a 405 nm laser as a light source, and the TRPL spectrum was obtained using a streak camera (Hamamatsu Photonics of Usho Optical Systems Co. Ltd.) and a 337 nm nitrogen pulse laser.

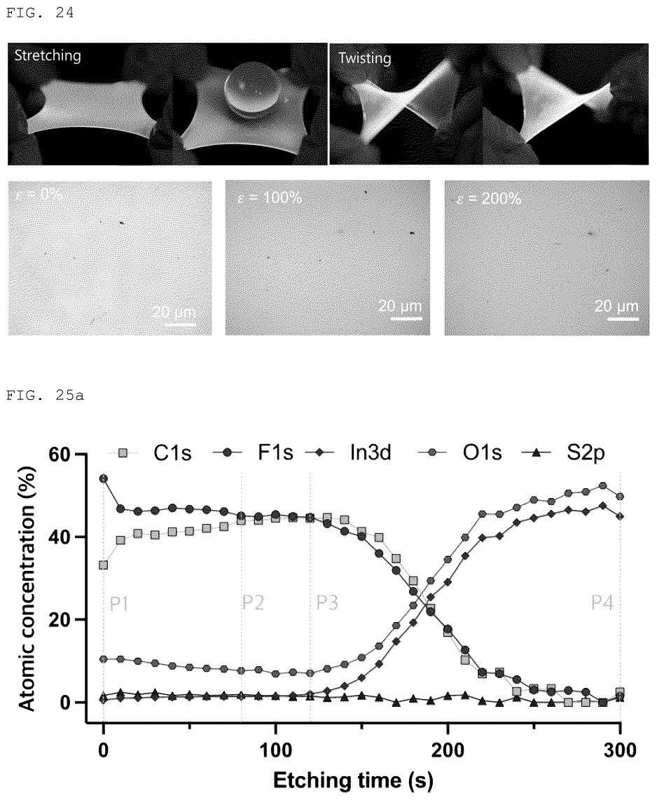

FIG. 22a is a diagram showing the Magneto-PL analysis results on the TADF-based stretchable light-emitting layer (4CzIPN:PU) and the phosphorescence-based stretchable light-emitting layer (Ir(ppy)₂acac:PU).

FIG. 22b is a diagram showing the TRPL analysis results on the TADF-based stretchable light-emitting layer (4CzIPN:PU) and the phosphorescence-based stretchable light-emitting layer (Ir(ppy)₂acac:PU).

Referring to FIGS. 22a and 22b, it may be identified that when stretched, the light-emitting layer including 4CzIPN, a TADF molecule, has an increased intermolecular distance has significantly reduced SOC, and consequently has reduced triplet collection efficiency. In addition, the light-emitting layer including 4CzIPN, a TADF molecule, had a PL peak red-shifting by about 12 nm under the tensile strain condition of 50%, and this indicates that a broader emission spectrum is caused by local aggregation of the 4CzIPN molecules due to the tensile strain.

On the other hand, it was identified that triplet collection efficiency was maintained in the phosphorescence-based stretchable light-emitting layer according to one embodiment of the present disclosure due to strong SOC even under the tensile strain condition during stretching, and the PL peak did not shift at all under the tensile strain condition of 50%. In other words, it was identified that the phosphorescence-based stretchable light-emitting layer has integrity when strained, and therefore, is suitable to be used in a stretchable organic light-emitting diode intended to be obtained in the present disclosure.

### (2) Identification of Thermoplastic Polyurethane Effect

Using each of the solutions for forming a stretchable light-emitting layer prepared in Preparation Example 3 and Comparative Preparation Example 2, a phosphorescence-based stretchable light-emitting layer was prepared as a test specimen in the same manner as in (1) comparative experiment on the TADF-based light-emitting layer and the phosphorescence-based stretchable light-emitting layer.

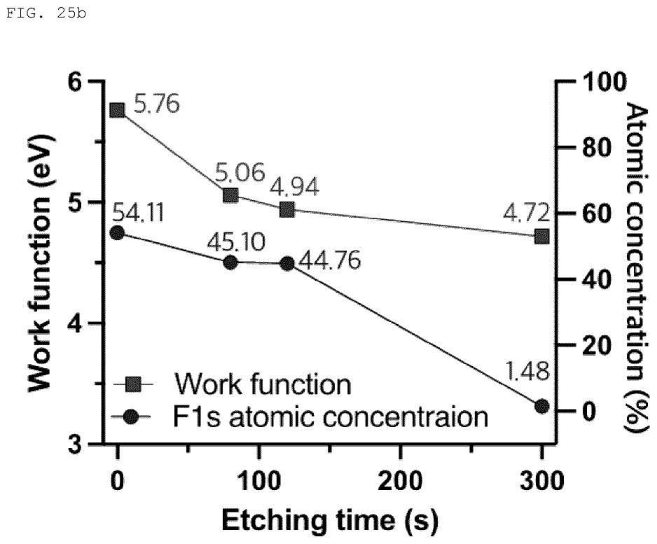

FIG. 23 shows atomic force microscope images of the stretchable light-emitting layer including thermoplastic polyurethane and SEBS elastomer as a matrix of the light-emitting layer. Referring to FIG. 23, it was identified that phase separation and aggregation phenomenon was observed when using the nonpolar SEBS elastomer as a matrix of the light-emitting layer, whereas compatibility with other materials was excellent when using the thermoplastic polyurethane.

### (3) Experiment on Tensile Strain of Phosphorescence-Based Stretchable Light-Emitting Layer

A stretchable light-emitting layer obtained by spin-coating the solution for forming a stretchable light-emitting layer prepared in Preparation Example 3 on a substrate including an SEBS elastomer at 2000 rpm for 60 seconds was prepared as a test specimen.

The image of the stretchable light-emitting layer was taken while applying biaxial tensile strain and twisting strain to the test specimen, and optical microscope images were taken when the tensile strain (F) was 0%, 100% and 200%.

FIG. 24 shows photographs taken when applying tensile strain and twisting strain to the phosphorescence-based stretchable light-emitting layer deposited on the SEBS elastomer substrate, and optical microscope images taken when the tensile strain (F) is 0%, 100% and 200%. Referring to FIG. 24, it was identified that the phosphorescence-based stretchable light-emitting layer deposited on the SEBS elastomer substrate exhibited excellent luminous performance even under biaxial tensile strain and twisting strain, and it was identified that no cracks were formed even when the tensile strain (F) was 200% as well as 100%.

### <Stretchable Hole Injection Layer>

### Preparation Example 4: Solution for Forming Stretchable Hole Injection Layer

1 wt % of Triton-X 100 was added to poly(3,4-ethylenedioxythiophene):poly(styrenesulfonate) (PEDOT:PSS, Clevios™ P VP AI4083) to obtain a mixture, and this mixture and perfluorosulfonic acid (PFSA) were mixed in a weight-to-weight ratio of 1:1.5 to prepare a solution for forming a stretchable hole injection layer.

### Experimental Example 3. Analysis on Properties of Stretchable Hole Injection Layer

### (1) Identification of Concentration Gradient and Work Function Gradient in Layer Thickness Direction

First, the solution for forming a stretchable hole injection layer prepared in Preparation Example 4 was spin-coated on a thoroughly washed glass substrate at 2000 rpm for 60 seconds. The glass substrate was separated by placing the result in water to prepare a stretchable hole injection layer prepared from Preparation Example 4 as a test specimen.

In order to identify the gradients of atomic concentration and work function of the stretchable hole injection layer in the layer thickness direction, the positions (P1, P2, P3 and P4) at the time when Ar sputter etching was performed for 0 second, 80 seconds, 120 seconds and 200 seconds, respectively, on the stretchable hole injection layer were analyzed by X-ray photoelectron spectroscopy (XPS) and ultraviolet photoelectron spectroscopy (UPS) spectrum. The XPS analysis was performed by scanning using a monochromatic Al Kα radiation source (1486.6 eV), and the UPS analysis was performed in the same manner as described in (3) work function of MXene-contact stretchable electrode of Experimental Example 1.

FIG. 25a is a diagram showing the XPS analysis and the UPS analysis results depending on the depth of the stretchable hole injection layer prepared using the solution of Preparation Example 4. FIG. 25b is a diagram showing work function and F is atomic content depending on the depth of the stretchable hole injection layer prepared using the solution of Preparation Example 4. Referring to FIG. 25a, the fluorine atom content was high when the sputter etching time was 0 seconds and 80 seconds, and this indicates that PFSA, a perfluorinated compound, forms a self-assembled layer in which fluorine atoms are concentrated near the surface of the stretchable hole injection layer. Referring to FIG. 25b, it was identified that, since fluorine atoms have high ionization potential, the work function decreased as the concentration of the fluorine atoms decreased, and the stretchable hole injection layer had a work function gradient depending on the depth.

### <Stretchable Organic Light-Emitting Diode>

### Example 7: Manufacture of Intrinsically-Stretchable Organic Light-Emitting Diode (ISOLED)

The solution for forming a stretchable hole injection layer prepared in Preparation Example 4 was mixed in a roller for 1 hour before being used in the device manufacturing, and the solution for forming a stretchable light-emitting layer prepared in Preparation Example 3 was prepared 12 hours before being used in the device manufacturing.

First, the solution for forming a stretchable hole injection layer was filtered through a 0.45 μm syringe PVDF filter, and then spin-coated on the work function adjustment layer of A-MCSE of Example 2 at 4000 rpm for 60 seconds. After that, a dense stretchable hole injection layer that resists THF solvent attack was formed by going through heat treatment for 30 minutes at 100° C. under an ambient air atmosphere. Herein, the stretchable hole injection layer formed had a thickness of approximately 82 nm.

After forming the stretchable hole injection layer, a substrate was transferred to a glove box environment. First, the solution for forming a stretchable light-emitting layer was filtered through a 0.2 μm syringe PVDF filter, and then spin-coated on the stretchable hole injection layer at 3000 rpm for 60 seconds. After that, the result was heat-treated for 5 minutes at 90° C. to form the stretchable light-emitting layer. Herein, the stretchable light-emitting layer formed had a thickness of approximately 50 nm.

Then, in order to set an electrical interface between the stretchable light-emitting layer and the stretchable electrode of Example 3, the electrode was gently placed on the stretchable light-emitting layer and pressed with tweezers to discharge trapped air bubbles. Then, the laminate was heat-treated for 15 minutes at 50° C. to manufacture a stretchable organic light-emitting diode while securing a substantial electrical contact. A copper tape was used to establish electrical connection. Lastly, in order to protect the stretchable organic light-emitting diode from oxygen and moisture, the stretchable organic light-emitting diode was encapsulated between two layers of SEBS film through drop casting in a glove box.

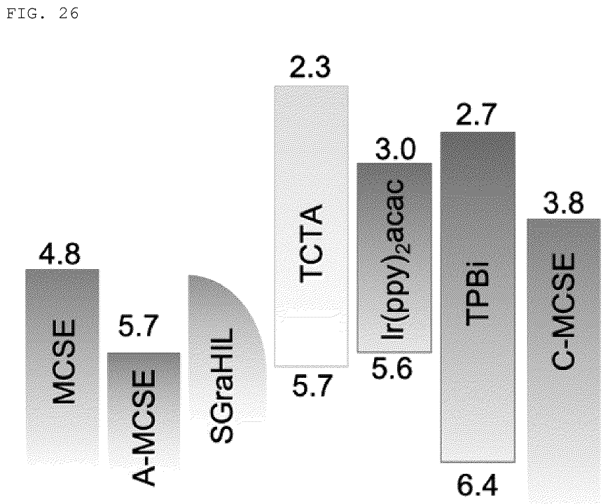

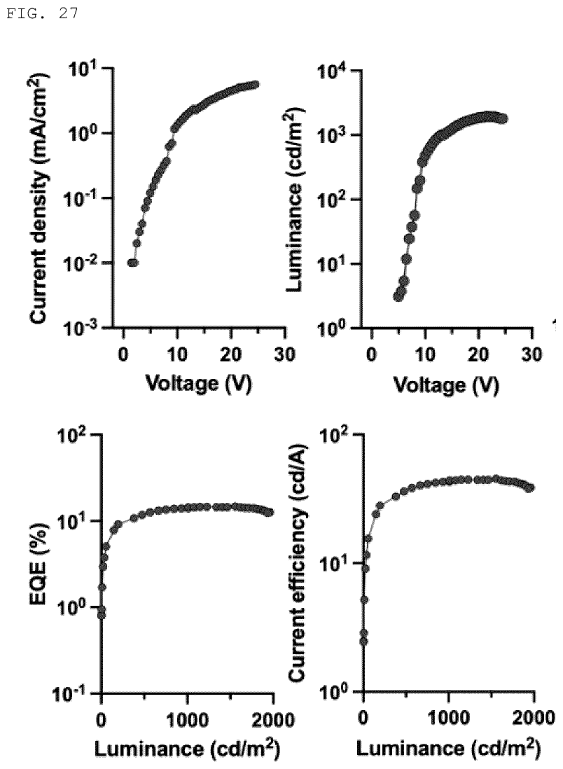

FIG. 26 is a diagram schematically illustrating an energy band of the stretchable organic light-emitting diode manufactured in Example 7.

### Experimental Example 4. Evaluation on Performance of Stretchable Organic Light-Emitting Diode

In order to evaluate performance of the stretchable organic light-emitting diode manufactured in Example 7, current density, luminance, external quantum efficiency (EQE) and current efficiency of the light-emitting diode were measured in a glove box filled with nitrogen gas. Radioactive properties were evaluated using an angle measurement setup in which a calibrated photodetector and a spectrometer are mounted on a rotating arm perpendicular to the device.

FIG. 27 is a diagram showing current density, luminance, external quantum efficiency (EQE) and current efficiency of the stretchable organic light-emitting diode manufactured in Example 7.

Referring to FIG. 27, it may be identified that all of current density, luminance, external quantum efficiency (EQE) and current efficiency of the stretchable organic light-emitting diode manufactured in Example 7 meet excellent levels. Properties and performance of the stretchable organic light-emitting diode according to the present disclosure manufactured in Example 7 are shown in the following Table 2.

TABLE 2

| | | \| | | | | External | |
|---|---|---|---|---|---|---|---|
| | | | | | | Quantum | |
| | | Triplet | Single/ | Maximum | Current | Efficiency, | Maximum |
| | Luminescence | Collection | Multi | Strain | Efficiency | EQE | Luminance |
| | Type | (Y/N) | Component | (%) | (cd/A) | (8) | (cd/m²) |
| Example | Phosphorescence | Y | Multi | 100 | 45.3 | 14.8 | 1962 |
| 7 | | | | | | | |

In Table 2, the maximum strain (%) means a tensile strain (%) at the time when luminance of the light-emitting diode decreases to 50% with respect to initial luminance. Referring to Table 2, it may be identified that the stretchable organic light-emitting diode according to the present disclosure has high current efficiency, external quantum efficiency and maximum luminance compared to stretchable organic light-emitting diodes previously reported. Furthermore, it may be identified that the tensile strain at the time when luminance of the light-emitting diode decreases to 50% with respect to initial luminance reaches 100%, and luminous performance is superior even in a stretched state while having excellent stretchability.

Hereinbefore, the present disclosure has been described with limited examples, however, the present disclosure is not limited thereto, and it is obvious that various changes and modifications may be made by those skilled in the art within technical ideas of the present disclosure and the range of equivalents of the claims to be described.

### REFERENCE NUMERAL

01: Contact layer including MXene
02: Conductive layer
03: Substrate
04: Work function adjustment layer
021: Conductive nanowires
022: Elastomer
10: Stretchable electrode
20: Cathode
30: Anode
40: Stretchable organic light-emitting layer
50: Stretchable hole injection layer
60: Electrolyte
100: Stretchable organic light-emitting diode
200: Actuator element
300: Self-actuating stretchable organic light-emitting diode

1. A stretchable electrode comprising:
a substrate including an elastomer,
a conductive layer including conductive nanowires having at least some thereof being embedded in the substrate; and
a contact layer positioned on the conductive layer and including MXene, and having an outer peripheral surface surrounded by the substrate,
wherein the MXene has an interlayer spacing (d-spacing) of 1.01 nm to 1.27 nm.

2. The stretchable electrode of claim 1, further comprising a MXene binder that is positioned at the interface between MXene contact layer and conductive nanowires and the interface between adjacent conductive nanowires, and adheres the MXene and the conductive nanowire.

3. The stretchable electrode of claim 2, wherein the MXene binder includes MXene expressed by Mₙ₊₁XₙTₓ,
wherein, M is a transition metal,
X is carbon (C), nitrogen (N) or a combination thereof,
Tₓ is a surface termination including oxide (O), hydroxide (OH), fluoride (F) or a combination thereof, and
n is an integer of 1 to 4.

4. The stretchable electrode of claim 1, wherein the stretchable electrode has a work function in the range of 2.0 eV to 7.0 eV.

5. The stretchable electrode of claim 1, further comprising a work function adjustment layer on the contact layer,
wherein the work function adjustment layer includes one or more types selected from the group consisting of polyethyleneimine (PEI); polyethyleneimine ethoxylated (PEIE); Poly[(9,9-bis(3′-(N,N-dimethyl)-N-ethylammonium-propyl)-2,7-fluorene)-alt-2,7-(9,9-dioctylfluorene)] dibromide (PFN-Br); a polymer compound represented by the following Chemical Formula 1; and derivatives thereof, 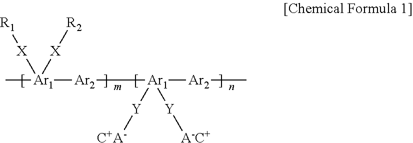
in Chemical Formula 1,
Ar₁ and Ar₂ are a main chain having a conjugated structure, and each independently at least one selected from among fluorene, spirofluorene, carbazole, thiophene, phenylene, phenylene vinylene and derivatives thereof, or more specifically any one selected from the following first compound group;
m and n are each independently an integer of 1 to 1,000,000;
m:n, which is a ratio between the number of repeating units, satisfies 0.1:0.9 to 1:0;
A⁻ is any one selected from among SO₃⁻, PO₃²⁻ and CO₂⁻;
C⁺ is any one selected from among H⁺, Li⁺, Na⁺, K⁺, Rb⁺, Cs⁺ and NH₄⁺;
X is —CₙH₂ₙ—O— (n is an integer of 1 to 20), and Y is —CₙH₂ₙ— (n is an integer of 1 to 20); and
R₁ and R₂ each independently bond to carbon of a substituted or unsubstituted crown ether compound:

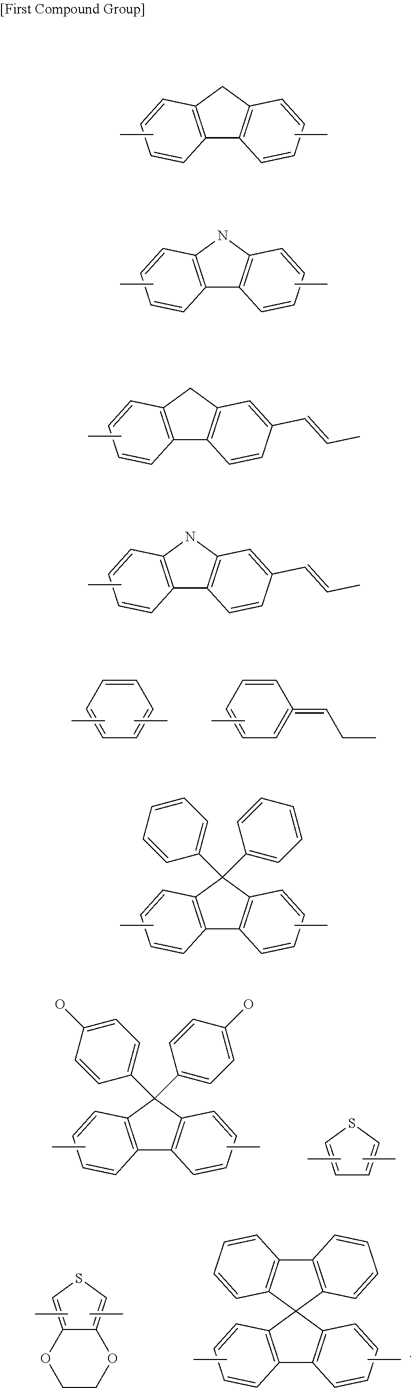

6. The stretchable electrode of claim 1, further comprising a work function adjustment layer on the contact layer,
wherein the work function adjustment layer includes one or more types selected from the group consisting of perfluorinated organic compounds, AuCl₃, HNO₃ and derivatives thereof.

7. The stretchable electrode of claim 1, which has optical transmittance of 85% or greater and 95% or less at a wavelength of 550 nm.

8. The stretchable electrode of claim 1, which has sheet resistance of 1 f/sq or greater and 30 f/sq or less.

9. The stretchable electrode of claim 1, wherein, when the stretchable electrode has a tensile strain of 40%, a rate of change in resistance calculated by the following Equation 1 is 100% or less:
$$rate of change in resistance ( \% ) = [ ( R - {R}_{0} ) / {R}_{0} ] \times 100 ( {R}_{0} is a resistance value measured for the \\ stretchable electrode that has not undergone tensile strain , \\ and R is a resistance value measured for the \\ stretchable electrode that has undergone tensile strain ) . \qquad [ Equation 1 ]$$

10. The stretchable electrode of claim 1, wherein, when the stretchable electrode has a tensile strain of 60%, a rate of change in resistance calculated by the following Equation 1 is 300% or less:
$$rate of change in resistance ( \% ) = [ ( R - {R}_{0} ) / {R}_{0} ] \times 100 ( {R}_{0} is a resistance value measured for the \\ stretchable electrode that has not undergone tensile strain , \\ and R is a resistance value measured for the \\ stretchable electrode that has undergone tensile strain ) . \qquad [ Equation 1 ]$$

11. A stretchable organic light-emitting diode comprising:
a cathode;
an anode facing the cathode;
a stretchable light-emitting layer positioned between the cathode and the anode; and
a stretchable hole injection layer positioned between the anode and the stretchable light-emitting layer,
wherein the cathode and the anode are the stretchable electrode of claim 1.

12. A stretchable organic light-emitting diode comprising:
a cathode;
an anode facing the cathode;
a stretchable light-emitting layer positioned between the cathode and the anode; and
a stretchable hole injection layer positioned between the anode and the stretchable light-emitting layer,
wherein the cathode is the stretchable electrode of claim 5.

13. A stretchable organic light-emitting diode comprising:
a cathode;
an anode facing the cathode;
a stretchable light-emitting layer positioned between the cathode and the anode; and
a stretchable hole injection layer positioned between the anode and the stretchable light-emitting layer,
wherein the anode is the stretchable electrode of claim 6.

14. The stretchable organic light-emitting diode of claim 11, wherein the stretchable light-emitting layer includes a thermoplastic polyurethane matrix; a co-host dispersed in the thermoplastic polyurethane matrix and forming an exciplex; and a phosphorescent dopant dispersed in the thermoplastic polyurethane matrix.

15. The stretchable organic light-emitting diode of claim 11, wherein the stretchable hole injection layer includes a surfactant, a conductive polymer and a perfluorinated compound.

16. The stretchable organic light-emitting diode of claim 15, wherein the stretchable hole injection layer has a work function gradually increasing in a direction of the stretchable organic light-emitting layer.

17. A method for manufacturing a stretchable organic light-emitting diode, wherein the diode comprises:
a cathode;
an anode facing the cathode; and
a stretchable light-emitting layer positioned between the cathode and the anode; and a stretchable hole injection layer positioned between the anode and the stretchable light-emitting layer; and
wherein the method comprising:
preparing the stretchable electrode of claim 1;
forming a stretchable hole injection layer by coating a solution for forming a stretchable hole injection layer on the stretchable electrode;
forming a stretchable organic light-emitting layer by coating a solution for forming a stretchable organic light-emitting layer on the stretchable hole injection layer; and
locating the stretchable electrode on the stretchable organic light-emitting layer and heat-treating the result.

18. The method of claim 17, wherein the preparing of the stretchable electrode includes:
forming a contact layer by coating a solution including MXene on a substrate;
adjusting an interlayer spacing (d-spacing) of the MXene to 1.01 nm to 1.27 nm by heat-treating the contact layer;
forming a conductive layer by coating a solution including conductive nanowires on the heat-treated contact layer,
forming a substrate by coating a solution including an elastomer on the conductive layer, and obtaining a laminate; and
separating the substrate from the laminate.

19. The method of claim 18, wherein the preparing of the stretchable electrode further includes, before the forming of a substrate and the obtaining of a laminate, forming a MXene binder by coating a diluted MXene solution on the conductive layer.

20. The method of claim 18, wherein the forming of a contact layer is performed by spin coating.
